(19) United States
(12) Patent Application Publication
(10) Pub. No.: US 2004/0145273 A1
(43) Pub. Date: Jul. 29, 2004

(54) Electronic driver circuit for high-speed actuation of high-capacitance actuators

(76) Inventors: James M. Khoury, Strongsville, OH (US); William J. Hassler JR., Cincinnati, OH (US); Gordon (ED) Bloom, San Rafael, CA (US)

Correspondence Address: CALFEE, HALTER & GRISWOLD, LLP, 800 SUPERIOR AVENUE, SUITE 1400, CLEVELAND, OH, 44114, US

(21) Appl. No.: 10/285,320

(22) Filed: Oct. 31, 2002

(51) Int. Cl. H01L 41/09

(52) U.S. Cl. 310/316.03

(57) ABSTRACT

An improved electronic driver circuit that is particularly effective at high-speed activation of high-capacitance devices, such as ceramic multilayer piezoelectric actuators, generating a high-voltage driver signal that is proportional to an input signal. The driver circuit has a relatively high power efficiency, having power dissipation losses that are much less than linear drivers in the same application. The driver circuit preferably operates as a switched mode, bidirectional, flyback converter in which energy is transferred from a capacitor to a high-capacitance device as the high-capacitance device is charged and energy is transferred back from the high-capacitance device to said charge storage device as the high-capacitance device is discharged. The driver circuit preferably has two control units—one for controlling charging of the high-capacitance device and the other for controlling the discharging of the high-capacitance device. In either case, the operational frequency of a control signal of the control unit controlling discharging is preferably reduced to permit the high-capacitance device to be discharged more rapidly.

### FIELD OF THE INVENTION

The present invention relates generally to the field of electronic driver circuits, and more specifically to an electronic driver circuit suitable for high-speed actuation of high-capacitance devices, such as ceramic multilayer piezoelectric actuators.

### BACKGROUND OF THE INVENTION

Automatic fluid dispensing systems that apply fluids, such as for example, adhesives, solder flux, sealants or other fluids, are used extensively in the automatic assembly and automatic packaging of products on assembly lines. As the speed of assembly lines increase, the automatic fluid dispensing systems must have a corresponding increase in speed. It is now common for assembly lines to require fluids to be dispensed at speeds on the order of 500 to 1000 discrete fluid applications per second or higher. The system discussed in U.S. Pat. No. 6,157,115 (“the '115 patent”), which is assigned to the assignee of the present case, uses a pair of piezoelectric actuators and a mechanical amplifier connected to flow control devices for dispensing fluids. The piezoelectric system taught in the '115 patent is suitable for high-speed actuation of flow control devices in automatic fluid dispensing systems.

In general, piezoelectric actuators function by relying on a fundamental principal of piezoelectric materials: when a voltage is applied to a piezoelectric structure, it expands. Typical piezoelectric actuators are formed of numerous piezoelectric elements that are stacked (e.g., ceramic multilayer piezoelectric actuators), requiring that several hundred volts be applied to cause the expansion of the entire stack.

Piezoelectric actuators, like those used in the system of '115 patent, behave electrically in much the same way that capacitors do. The Sumitomo model 20B piezoelectric device mentioned in the '115 patent has a capacitance of about 2.5 μF. Piezoelectric actuators can be driven by a number of different types of drivers, such as high-voltage linear drivers. However, linear drivers are quite inefficient. Because of the relatively high currents (on the order of 1-10 amperes) and the relatively high voltages (on the order of hundreds of volts) needed to drive piezoelectric actuators, the losses tend to be unacceptable when high-voltage linear drivers are used to drive piezoelectric actuators. For example, charging and discharging a single 2.5 μF capacitor load between 0 and 200 volts at a rate of 1000 Hz represents an average power transfer of about 50 watts between the driver and load. A typical class A linear amplifier would dissipate over 100 watts in this application. Driving a pair of piezoelectric actuators, as taught in the '115 patent, with such a linear driver would dissipate an unacceptable amount of energy.

There is a need, therefore, for an improved electronic driver circuit to actuate high-voltage capacitive loads, such as ceramic multilayer piezoelectric actuators in high-speed dispensing applications (on the order of 500 Hz and higher).

### SUMMARY OF THE INVENTION

The present invention is directed toward an improved electronic driver circuit for high-speed actuation of high-voltage capacitive loads, such as ceramic multilayer piezoelectric actuators. The driver circuit according to the present invention preferably operates in a switching mode as a flyback converter that generates an output signal having a voltage that is proportional to the voltage of an input control signal. “Flyback converters” typically use a single semiconductor switch in conjunction with an inductor and operate by storing energy during a switch conduction time and releasing the stored energy when the switch is not conducting. Energy is typically stored in the inductor primary during the first half of the switching period when the switch is on, and during the second half of the switching period (or “flyback” period), when the transistor is off, this energy is transferred to the inductor secondary and load.

At one level, the driver circuit according to the present invention preferably comprises a voltage source having a charge storage device at a voltage output thereof, a power circuit in circuit communication with the voltage source at the voltage output and for being placed in circuit communication with the high-capacitance load, and a control circuit accepting a control input, the control circuit in circuit communication with the power circuit and controlling the power circuit to cause the charging and discharging of the high-capacitance load responsive to the control input, the control circuit characterized by operating so that electrical energy is transferred from the charge storage device to the high-capacitance load as the high-capacitance load is charged and electrical energy is transferred back from the high-capacitance load to the charge storage device as the high-capacitance load is discharged.

At another level, the driver circuit of the present invention preferably comprises a two-winding inductor component having a primary side and a secondary side, the second side for being placed in circuit communication with the high-capacitance load, a power source in circuit communication with the primary side, a charge storage device in circuit communication with the primary side, a primary side switch in circuit communication with the primary side and characterized by selectively causing current from the power source and/or the charge storage device to conduct through the primary side, a secondary side switch in circuit communication with the secondary side and characterized by selectively causing current from the high-capacitance load to conduct through the secondary side, and a control circuit in circuit communication with the primary side switch and the secondary side switch so as to control the charging and discharging of the high-capacitance load by the switches responsive to a control input, the control circuit characterized by operating in a switching mode as a flyback converter so that energy is transferred from the charge storage device to the high-capacitance load as the high-capacitance load is charged and energy is transferred back from the high-capacitance load to the charge storage device as the high-capacitance load is discharged.

At either level, the control circuit of the present invention preferably includes either two or one control units that control the charging and discharging of the high-capacitance load. In the case of the former, the control circuit includes first and second control units, with the first control unit characterized by primarily controlling the charging (“pumping up”) of the high-capacitance load, and the second control unit characterized by primarily controlling the discharging (“pumping down”) of the high-capacitance load. In the other case, a dual control unit control controls both the charging and discharging of the high-capacitance load. In this case, some portion of the driver circuit assists the dual control unit by determining whether the control unit should be charging or discharging the load and by directing signals therefrom to either charging circuitry or discharging circuitry, e.g., a slope detector and routing logic. In either case, one important aspect of the present invention is the ability to vary and reduce the operating frequency of the control unit controlling the discharge of the high-capacitance load, which has the effect of decreasing the discharge-time.

It is therefore an advantage of the present invention to provide a driver circuit to drive a high-capacitance load, e.g., ceramic multilayer piezoelectric actuators, with a high-voltage signal at frequencies of 500 Hz and higher.

It is also an advantage of the present invention to provide a driver circuit to drive a high-capacitance load, e.g., ceramic multilayer piezoelectric actuators, in which electrical energy is transferred back and forth between the high-capacitance load and a charge storage device.

It is another advantage of the present invention to provide a high-efficiency driver circuit to drive a high-capacitance load, e.g., ceramic multilayer piezoelectric actuators.

It is a further advantage of this invention to provide a driver circuit to drive a high-capacitance load, e.g., ceramic multilayer piezoelectric actuators, operating as a bi-directional switching-mode flyback converter. It an advantage of the present invention to provide a driver circuit to drive a high-capacitance load that operates as a bi-directional switching-mode flyback converter generating an output signal proportional to a control input signal.

It is still another advantage of the present invention to provide a driver circuit to drive a high-capacitance load, e.g., ceramic multilayer piezoelectric actuators, that includes a control circuit that controls discharge of the high-capacitance load, the control circuit having an operating frequency, and in which during discharge the operating frequency of the control circuit is reduced as the high-capacitance load discharges.

It is yet another advantage of the present invention to provide a driver circuit to drive a high-capacitance load, e.g., ceramic multilayer piezoelectric actuators, that includes a control circuit that increases the rate of energy transfer during discharge of the high-capacitance load by decreasing the operational frequency of a discharge control signal as the high-capacitance load discharges.

It is still another advantage of the present invention to provide a driver circuit to drive a high-capacitance load, e.g., ceramic multilayer piezoelectric actuators, that includes a control circuit that controls charging of the high-capacitance load, in which the control circuit is controlled in a plurality of modes, e.g., a current-controlled continuous-conduction (CCCC) energy storage mode, a current-controlled discontinuous-conduction (CCDC) energy storage mode, and a voltage-controlled discontinuous-conduction (VCDC) energy storage mode.

These and other advantages of the present invention will become more apparent from a detailed description of the invention.

### BRIEF DESCRIPTION OF THE DRAWINGS

In the accompanying drawings, which are incorporated in and constitute a part of this specification, embodiments of the invention are illustrated, which, together with a general description of the invention given above, and the detailed description given below, serve to example the principles of this invention, wherein:

FIG. 1 is a high-level block diagram of a one-channel electronic driver circuit according to the present invention;

FIG. 2 is a medium-level block diagram of a one-channel electronic driver circuit according to the present invention showing an embodiment of the power circuit according to the present invention;

FIG. 3A is a medium-level block diagram of a one-channel electronic driver circuit according to the present invention showing a first embodiment (two control units) of the control circuit according to the present invention and FIG. 3B shows some of the blocks of FIG. 3A rearranged so as to be more easily mapped (i.e., closer in arrangement) to the circuit shown in FIGS. 4A-4I;

FIGS. 4A-4I show exemplary circuit implementations of the various parts of the electronic driver circuit shown in FIG. 3A;

FIG. 5 is a schematic block diagram showing the internal circuitry of control unit U11 in FIG. 4H and some of the components interfacing therewith;

FIG. 6 is FIG. 15 of the '115 patent (except that the reference characters have been changed to match those herein);

FIG. 7 is a high-level block diagram of a two-channel electronic driver circuit according to the present invention;

FIG. 8 is a medium-level block diagram of a portion of the two-channel electronic driver circuit of FIG. 7, showing a 180° phase-shifter element;

FIG. 9 is a medium-level block diagram of the two-channel electronic driver circuit of FIG. 7;

FIG. 10 shows a circuit implementation of the 180° phase-shifter element shown in FIGS. 8 and 9;

FIG. 11 is a medium-level block diagram of a one-channel electronic driver circuit according to the present invention showing a second embodiment (one control unit) of the control circuit according to the present invention;

FIG. 12 is a schematic block diagram showing an overview of changes that can be made to the circuit implementation of FIGS. 4A-4I (and the two-channel version thereof) to implement the second embodiment (one control unit) of the control circuit according to the present invention shown in FIG. 11;

FIGS. 13A-13E are circuit schematic diagrams showing specific changes that can be made to the circuit implementation of FIGS. 4A-4I (and the two-channel version thereof) to implement the second embodiment (one control unit) of the control circuit according to the present invention shown in FIG. 11;

FIG. 14 is a timing diagram showing some of the signals of the circuitry of FIGS. 13C and 13D; and

FIGS. 15A-15C through FIGS. 28A-28C are actual waveform diagrams showing the two driver outputs of the circuit of FIGS. 4A-4I responsive to various input signals, at various magnifications (capture rates).

### DETAILED DESCRIPTION OF THE INVENTION

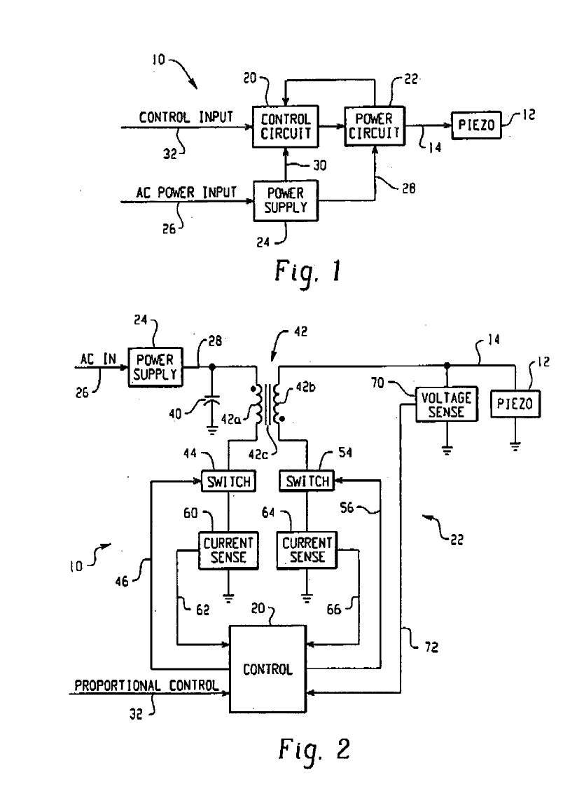

Referring to the figures, FIGS. 1 and 2 show a one-channel electronic driver circuit 10 according to the present invention. The driver circuit 10 in FIG. 1 is being used to drive a load 12, i.e., activate and deactivate load 12, with a driver signal 14. Load 12 can be a high-voltage, high-capacitance device such as a piezoelectric element, although the present invention is not necessarily so limited and may be used to drive a number of different elements and circuits. Thus the driver circuit 10 is preferably placed in circuit communication with load 12. “Circuit communication” as used herein indicates a communicative relationship between devices. Direct electrical, electromagnetic, and optical connections and indirect electrical, electromagnetic, and optical connections are examples of circuit communication. Two devices are in circuit communication if a signal from one is received by the other, regardless of whether the signal is modified by some other device. For example, two devices separated by one or more of the following—amplifiers, filters, transformers, optoisolators, digital or analog buffers, analog integrators, other electronic circuitry, fiber optic transceivers, or even satellites-are in circuit communication if a signal from one is communicated to the other, even though the signal is modified by the intermediate device(s). As another example, an electromagnetic sensor is in circuit communication with a signal if it receives electromagnetic radiation from the signal. As a final example, two devices not directly connected to each other, but both capable of interfacing with a third device, e.g., a CPU, are in circuit communication. Also, “high-capacitance” as used herein means on the order of 1 μF or greater.

Driver circuit 10 of the present invention preferably comprises a control circuit 20 in circuit communication with a power circuit 22. Practical considerations with respect to use of the driver circuit 10 will likely require a power supply 24 accepting a power input 26, such as an AC input, to generate one or more suitable high-voltage DC signals 28 to be converted by the power circuit 22 under control of the control circuit 20 to activate load 12 via driver signal 14 and also to generate one or more suitable low voltage signals 30 to power the circuitry making up the control circuit 20, the power circuit 22, and the power supply 24. The driver circuit 10 preferably accepts a control input 32 that controls the activation and deactivation of load 12 by driver circuit 10. The driver circuit 10 more preferably accepts a proportional control input 32 that controls the activation and deactivation of load 12 by driver circuit 10, with the driver signal 14 being approximately proportional to the proportional control input signal. Because of the relative high capacitance of the load 12, the relatively high activation voltage of load 12, and a desire to be able to activate and deactivate such a load 12 very quickly, the driver circuit 10 according to the present invention must be capable of very quickly providing a relatively high charge at a high voltage, that is, the driver circuit 10 according to the present invention must be capable of generating a high voltage, high current driver signal 14 in response to the control input 32. For example, to activate a piezoelectric actuator from Hoechst Ceramtec AG, Piezoceramics Product Group having dimensions of 30 mm×5 mm×5 mm (model number 39999-34.3) at 700 Hz, a driver must be able to source and sink about +200 volts DC at about 10 amperes. To accomplish these rapid, relatively high-power transfers, the control circuit 20 and the power circuit 22 preferably are characterized in that together they form a switching mode flyback converter.

Referring now to FIG. 2, additional information about the preferred power circuit 22 is shown. Power circuit 22 preferably comprises a charge storage device in circuit communication with a two-winding inductor 42. Inductor 42 preferably comprises a primary side 42a, a secondary side 42b, and a gapped magnetic core 42c. Primary side 42a is preferably in circuit communication with high-voltage signal 28 of power supply 24 and in circuit communication with charge storage device, which preferably comprises a capacitor 40. Primary side 42a is also preferably in circuit communication with a primary side switch 44, which is controlled by a control signal 46 generated by control circuit 20. Primary side switch 44, under control of control circuit 20 via control signal 46, selectively prevents and allows charge from the high-voltage signal 28 and/or from capacitor 40 to flow through primary side 42a of transformer 42. Secondary side 42b of transformer 42 preferably generates driver signal 14. Similar to the primary side 42a, secondary side 42b is preferably in circuit communication with a secondary side switch 54, which is controlled by a control signal 56 generated by control circuit 20. Secondary side switch 54, under control of control circuit 20 via control signal 56, selectively prevents and allows charge from the high-capacitance load 12 to flow through secondary side 42b of transformer 42. Control signals 46 and 56 are preferably pulse-width modulated signals.

Control circuit 20 preferably controls the charging and discharging of the actuator 12. During charging of the actuator 12, control circuit 20 preferably functions to cause power circuit 22 to accept voltage from power supply 24 and/or charge storage capacitor 40 and transfer the energy (charge) to the actuator 12. To discharge the actuator 12, control circuit 20 preferably functions to cause power circuit 22 to discharge the voltage stored by actuator 12 and transfer the actuator energy (charge) back to the charge storage capacitor 40. The control circuit 20 preferably accepts the control input 32 and controls power circuit 22 to activate and deactivate load 12. The control circuit 20 more preferably accepts proportional control input 32 and controls the power circuit 22 to create a driver signal 14 that is approximately proportional to the proportional control input signal 32.

Additionally, control circuit 20 also preferably accepts feedback from various portions of power circuit 22. For example, primary side 42a is preferably in circuit communication with a current sensor 60 that generates a signal 62 representing or otherwise related to a current flowing through the primary side 42a and/or the primary side switch 44. Similarly, secondary side 42b is preferably in circuit communication with a current sensor 64 that generates a signal 66 representing or otherwise related to a current flowing through the secondary side 42b and/or the secondary side switch 54. The primary side current signal 62 is preferably used by control circuit 20 to prevent the gapped magnetic core 42c of inductor 42 from saturating as energy is transferred from the high-voltage signal 28 and/or capacitor 40 via the primary side 42a to the gap 42c or to the secondary side 42b. More specifically, preferably, as the current through the primary side 42a reaches a predetermined threshold, control circuit 20 opens the primary switch 44 to prevent saturation of the core 42c. Similarly, the secondary side current signal 66 is preferably used by control circuit 20 to prevent the magnetic core 42c of inductor 42 from saturating as energy is transferred from the load 12 via the secondary side 42b back to the capacitor 40. More specifically, as the current through the secondary side 42b reaches a predetermined threshold, control circuit 20 opens the secondary switch 54 to prevent saturation of the core 42c.

In addition, control circuit 20 also preferably accepts feedback from and is preferably in circuit communication with a voltage sensor 70 that generates a signal 72 representing or otherwise related to a voltage of driver signal 14. The voltage signal 72 is preferably used by control circuit 20 to control driver signal 14. More specifically, preferably, control circuit 20 changes modes depending on how close the actuator voltage 14 is to the desired voltage indicated by input signal 32.

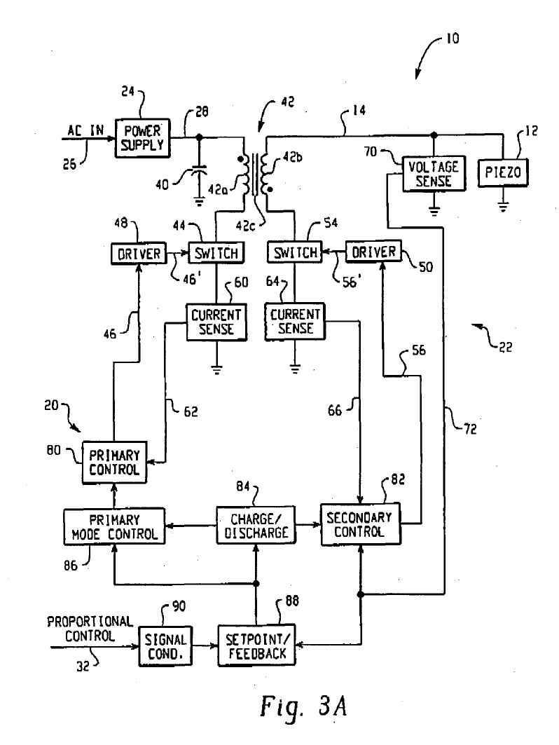

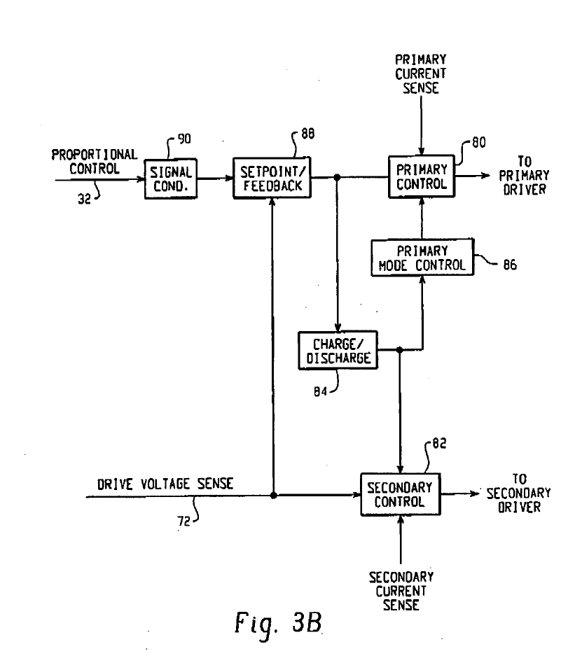

Referring now to FIG. 3A, additional information about the preferred control circuit 20 is shown. The control circuit 20 preferably comprises a primary control circuit 80 and a secondary control circuit 82. The primary control circuit 80 preferably controls the charging of actuator 12 via primary side control signal 46 generated by primary control circuit 80 and interfaced with and amplified by driver circuit 48 (the driven primary control signal is shown as 46′). Similarly, secondary control circuit 82 preferably controls the discharging of actuator 12 via secondary side control signal 56 generated by secondary control circuit 82 and interfaced with and amplified by driver circuit 50 (the driven primary control signal is shown as 56′). Control signals 46 and 56 (and driven control signals 46′ and 56′) are preferably pulse-width modulated (PWM) signals. The primary control circuit 80 and secondary control circuit 82 can be the same control circuit; however, in FIG. 3A they are separate circuits. The control circuit 20 also preferably has a charge/discharge circuit 84 in circuit communication with the primary control circuit 80 and the secondary control circuit 82, which determines which of the two control circuits 80, 82 is active at a given point in time. The primary control circuit 80 preferably uses the primary side current signal 62 to prevent the gapped magnetic core 42c of inductor 42 from saturating as energy is transferred from the high-voltage signal 28 and/or capacitor 40 via the primary side 42a of inductor 42. More specifically, preferably, as the current through the primary side 42a reaches a predetermined threshold, the primary control circuit 80 opens the primary switch 44 to prevent saturation of the core 42c. Similarly, the secondary control circuit 82 preferably uses the secondary side current signal 66 to prevent the core 42c of inductor 42 from saturating as energy is transferred from the load 12 via the secondary side 42b back to inductor 42 and subsequently to the capacitor 40. More specifically, preferably, as the current through the secondary side 42b reaches a predetermined threshold, the secondary control circuit 82 opens the secondary switch 54 to prevent saturation of the core 42c.

Additionally, the control circuit 20 may include one or more mode control circuits, e.g., primary mode control circuit 86, that selectively force a control circuit into one of several modes under different conditions and preferably in real-time, e.g., a current-controlled continuous-conduction (CCCC) energy storage mode (or just “CCCC mode”), a current-controlled discontinuous-conduction (CCDC) energy storage mode (or just “CCDC mode”), and a voltage-controlled discontinuous-conduction (VCDC) energy storage mode (or just “VCDC mode”). Primary mode control circuit 86 preferably causes primary control circuit 80 to selectively function in one of the following modes: CCCC, CCDC, and VCDC. In the CCCC mode and the CCDC mode, the current through the primary winding 42a is used to control the end of a given PWM switching cycle. In the VCDC mode, the driver voltage sense 72 (derived from the driver voltage) is used to control the end of a given PWM switching cycle. In the CCCC mode, the energy stored in inductor 42 never falls below zero during a switching period. In the CCDC and VCDC modes, the energy in inductor 42 does reduce to zero value between PWM cycles; there is a deadband during each cycle when no current is flowing in the primary winding 42a. In the CCCC mode, nominally the maximum allowable (i.e., without saturating the core 42c) amount of energy is delivered (taking into consideration tolerances, temperature effects, etc.). In the CCDC mode, the energy transferred is less than in the CCCC mode. The VCDC mode is used primarily when the driver voltage sense 72 (derived from the driver voltage) is close to its setpoint and is used to maintain the driver voltage at that setpoint. Thus, as the input signal 32 transitions from 0 VDC to, e.g., 12 VDC, the primary mode control circuit 86 preferably causes primary control circuit 80 to initially function in CCCC mode, then function in CCDC mode, and then finally to function in VCDC mode. More preferably, as the input signal 32 transitions from 0 VDC to, e.g., 12 VDC, the primary mode control circuit 86 preferably causes primary control circuit 80 to initially function in CCCC mode and then, in response to the driver voltage sense 72 (derived from the driver voltage) reaching a first predetermined threshold (e.g., approximately 65% of maximum output, approximately 130 volts for a maximum 200-volt output), the primary mode control circuit 86 causes the primary control circuit 80 to function in CCDC mode, and then, finally in response to the driver voltage 14 reaching a second predetermined threshold (e.g., approximately 80% of maximum output, approximately 160 volts for a maximum 200-volt output), the primary mode control circuit 86 causes the primary control circuit 80 to function in VCDC mode.

In addition, the control circuit 20 preferably includes setpoint/feedback circuitry 88 that helps the primary control circuit control the voltage level of the driver signal 14 in accordance with the proportional input signal 32. This circuitry 88 preferably accepts an actuator voltage feedback signal 72 that represents or is otherwise related to the voltage level of the driver signal 14. Of course, the input signal 32 preferably includes some form of signal conditioning by a signal conditioning circuit 90.

As seen in the figures, the two windings 42a, 42b of inductor 42 are shown in FIGS. 2 and 3 has being in circuit communication with different grounds. More specifically, the primary side 42a is shown as being preferably connected to the “hot” ground ( [symbol] symbol on the schematics) via primary switch 44 and primary current sense 60, and secondary side 42b is shown as being preferably connected to system ground ( [symbol] symbol) via secondary switch 54 and secondary current sense 64. Accordingly, the power supply 24 preferably has multiple electrically isolated rails forming low-voltage supplies 30, each of which are referenced to their respective grounds.

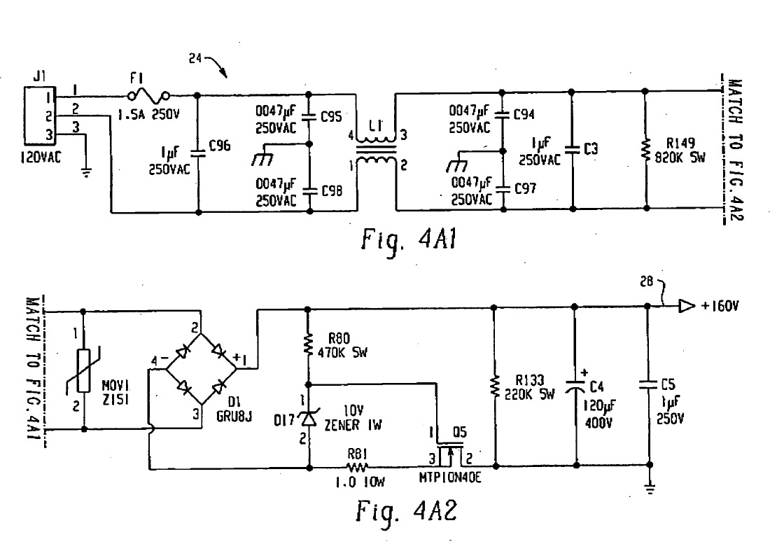

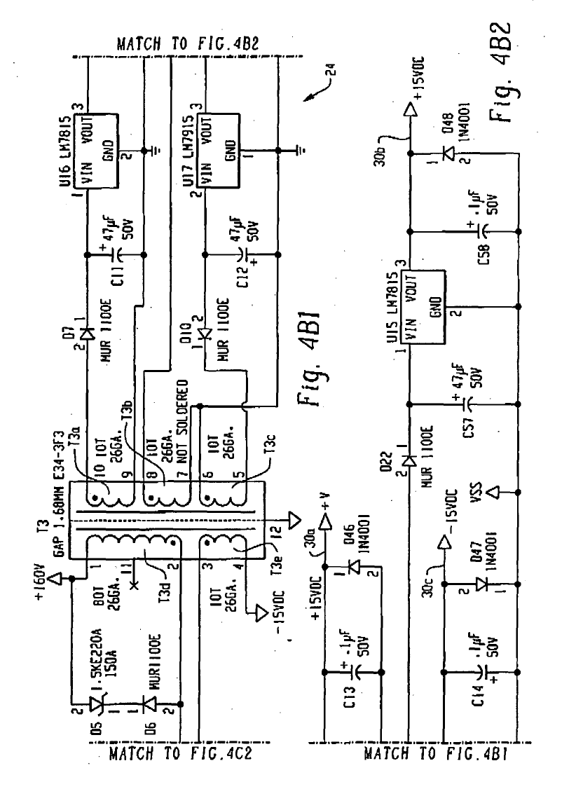

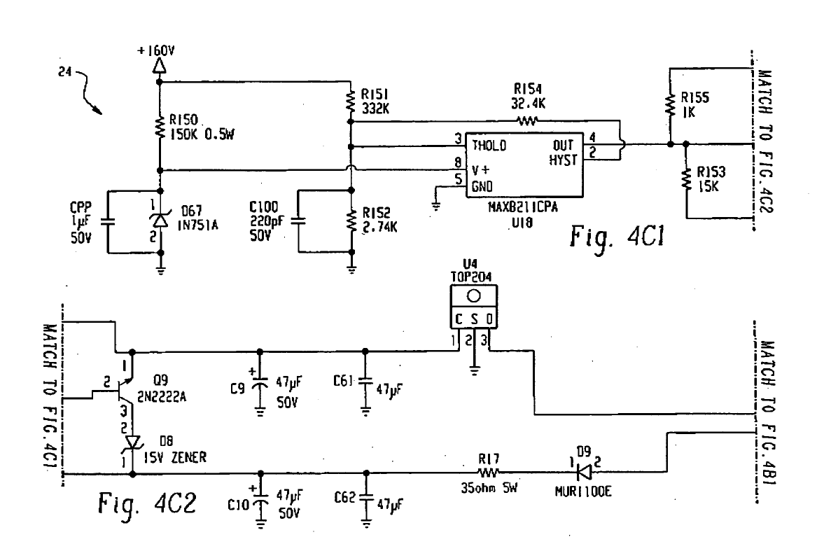

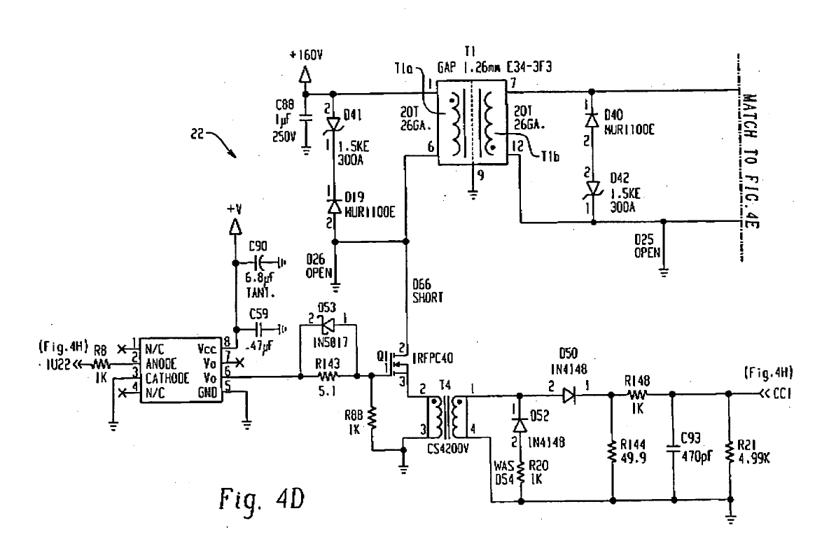

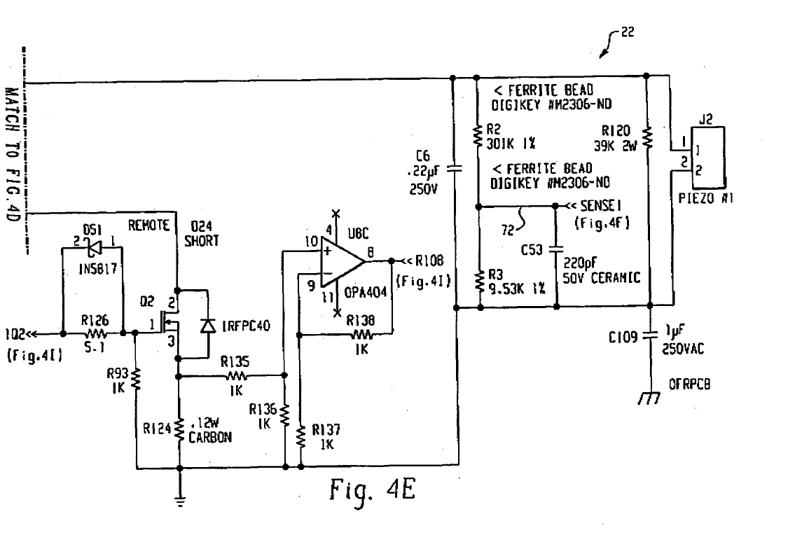

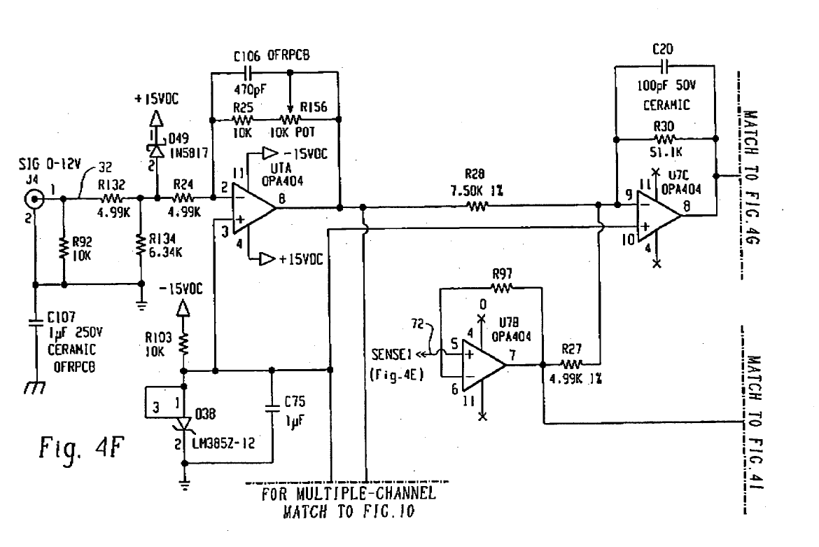

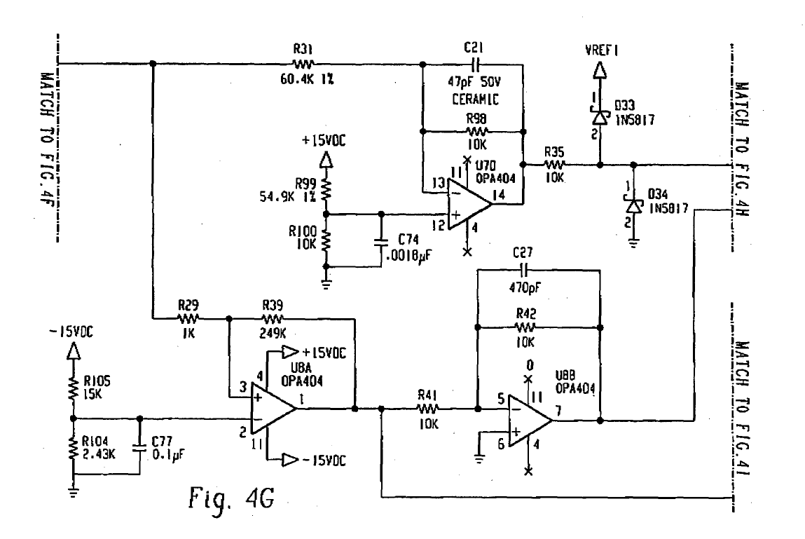

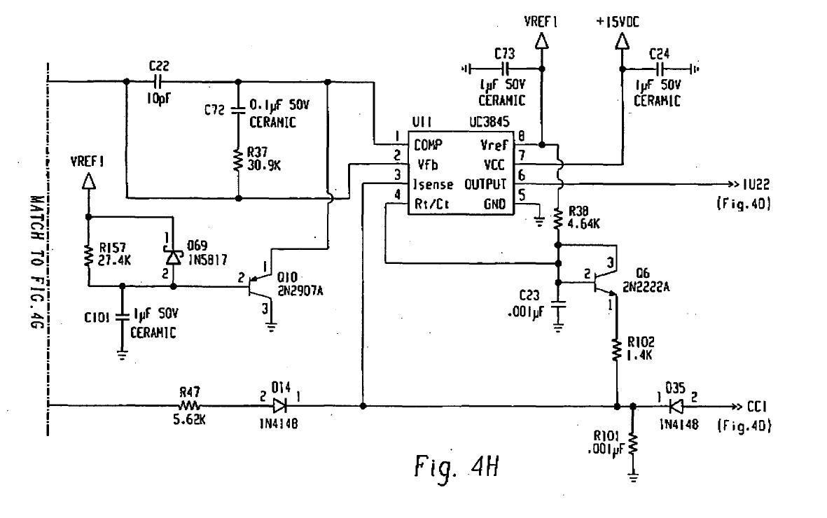

FIGS. 4A-4I together form a schematic diagram of a one-channel driver embodiment according to the present invention, preferably including the components shown in circuit communication as shown. The embodiment shown in FIGS. 4D-4I accepts a 0 to 12 volt proportional control input signal and generates a generally proportional 0 to 200 volt output. The embodiment of FIGS. 4D-4I can accept input signals having relatively high frequencies, e.g., 1000 Hz or higher (the actuators identified above cannot tolerate sustained use at that high of a frequency), and still generate an acceptable 0 to 200 volt proportional output signal. In this particular embodiment, at relatively low input signal frequencies the output signal tracks the input signal very closely. The output signal is generally proportional but not exactly proportional because, at higher frequencies the output signal tracks the input signal quite well as the input signal rises, but because of design considerations discussed below (PWM frequency is sequentially reduced during actuator discharge), as the input signal voltage falls (i.e., as charge is being removed from the load 12) the output signal does not track the input signal quite as well for inputs that are not square waves. In short, the implementation of FIGS. 4D-4I is optimized for square-wave input signals and its response performance suffers during discharging for non-square-wave inputs. The performance during discharging for non-square-wave inputs is a result of design trade-offs between faster discharge times and better discharge waveforms. Slowing the PWM frequency during discharge allows for a faster discharge time for a square-wave output, but has the effect of distorting non-square-wave outputs.

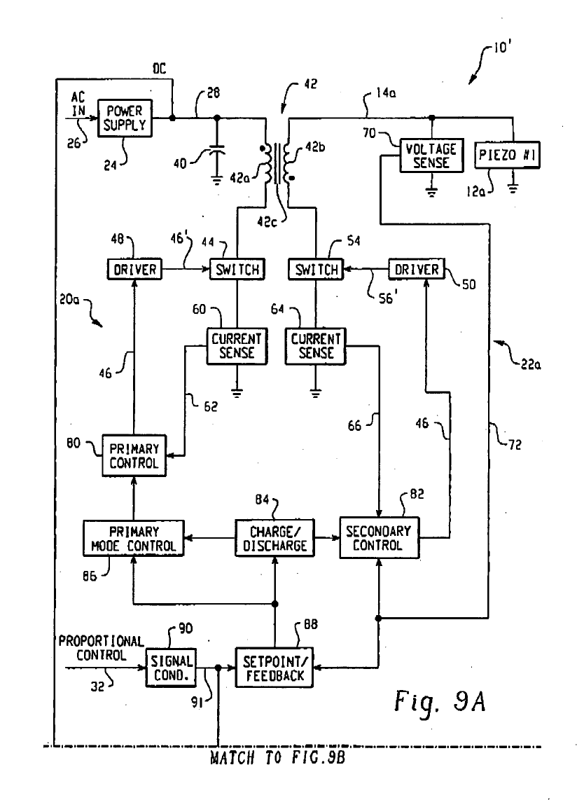

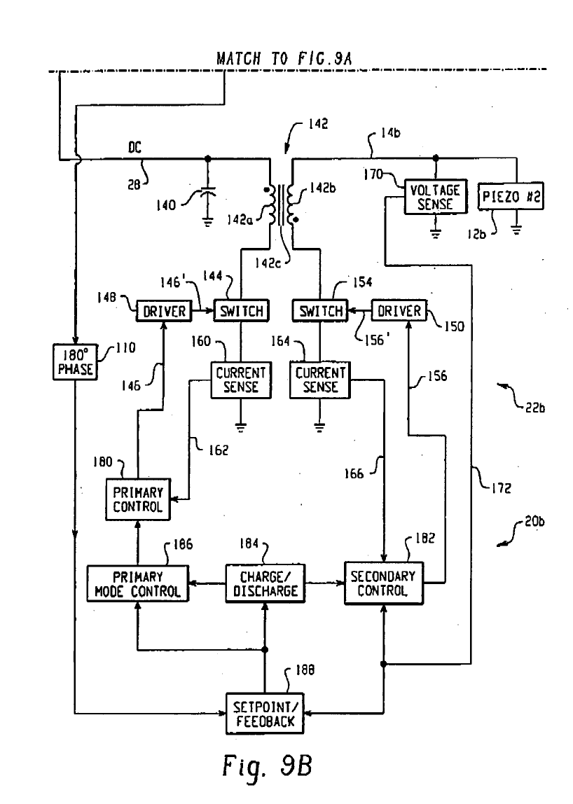

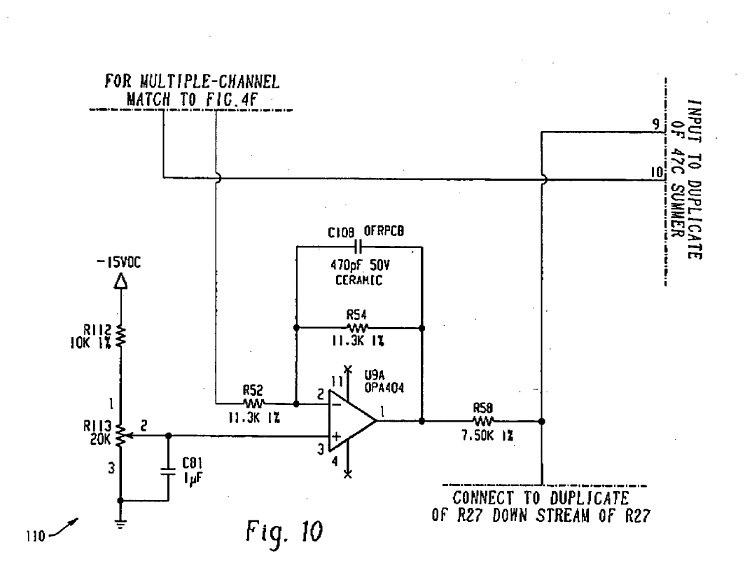

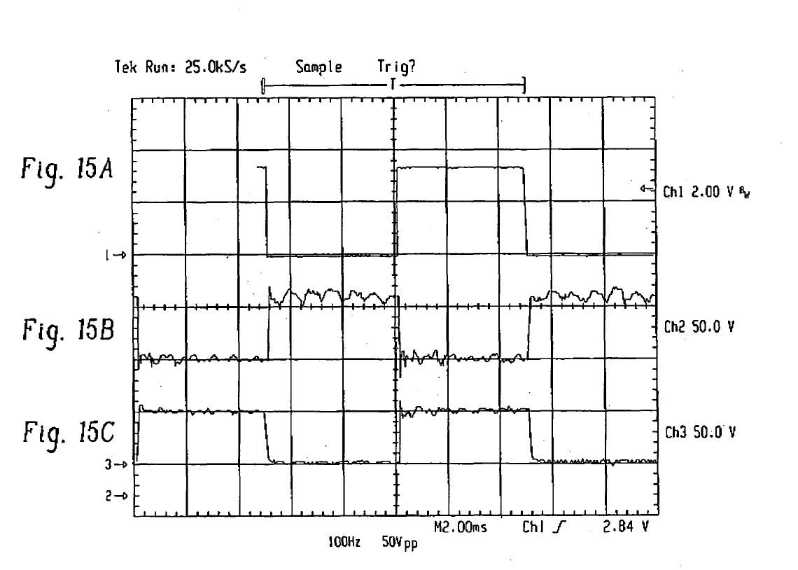

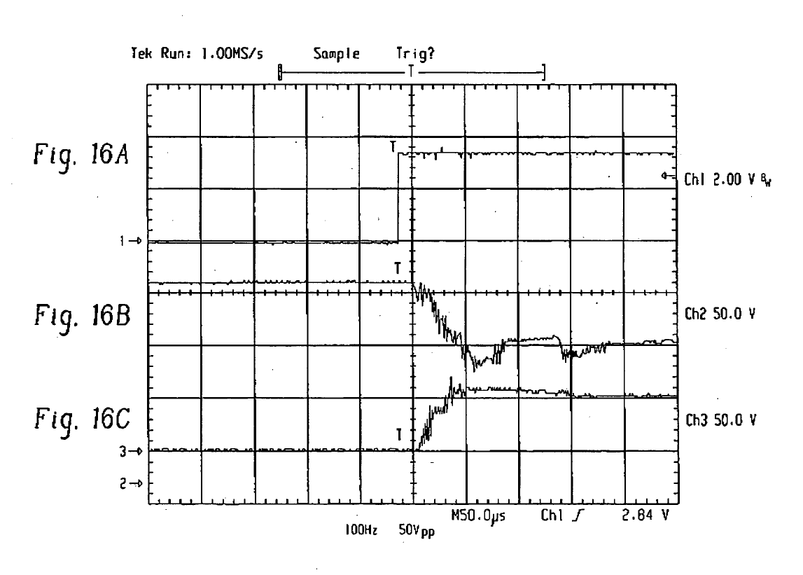

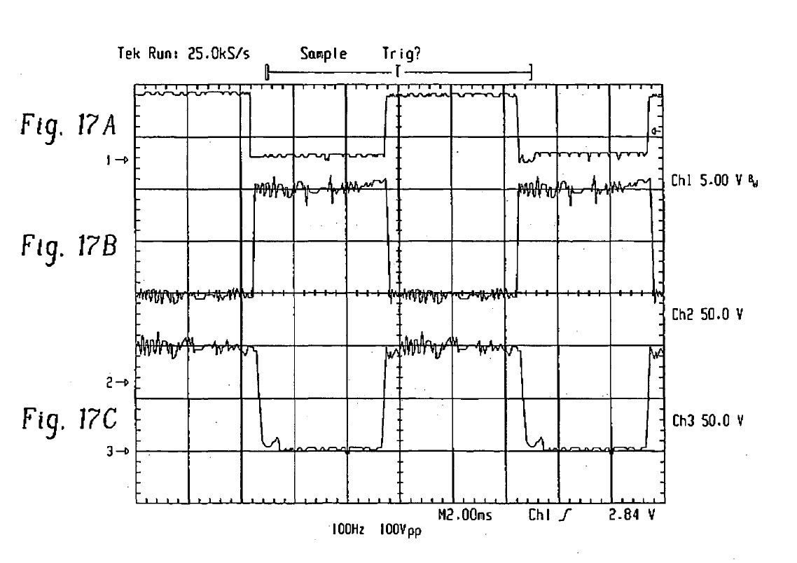

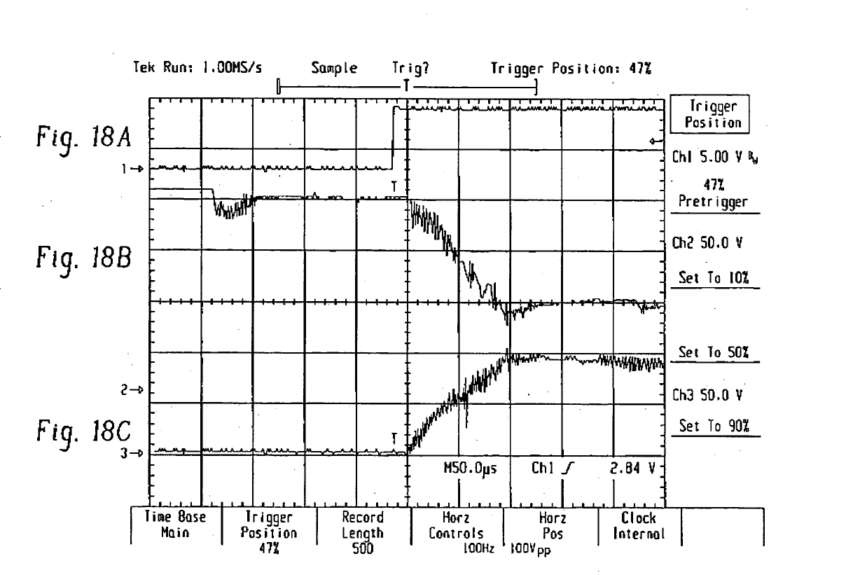

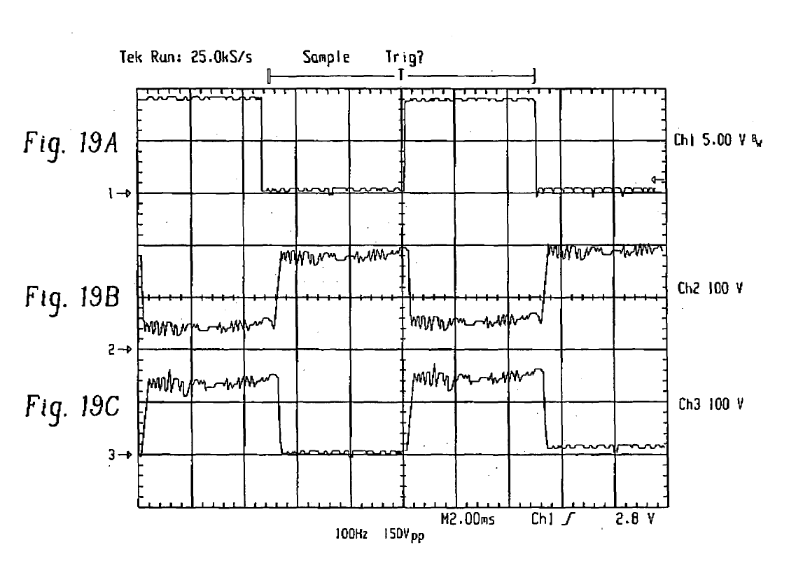

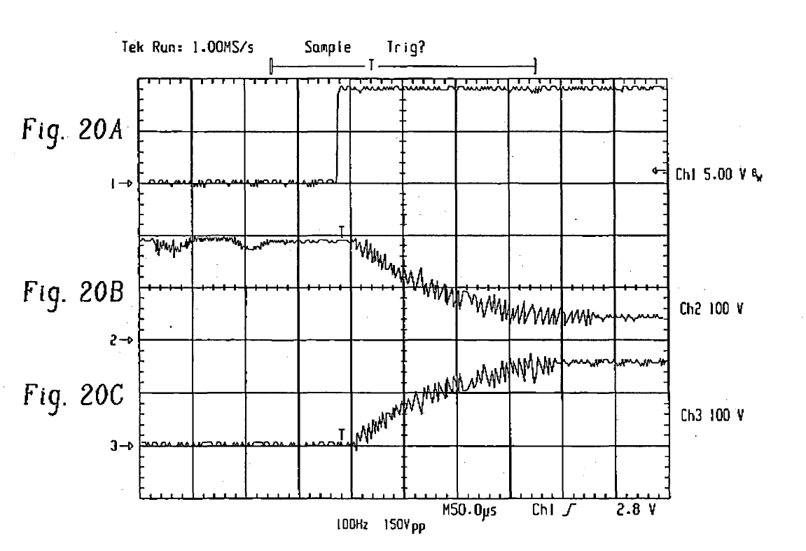

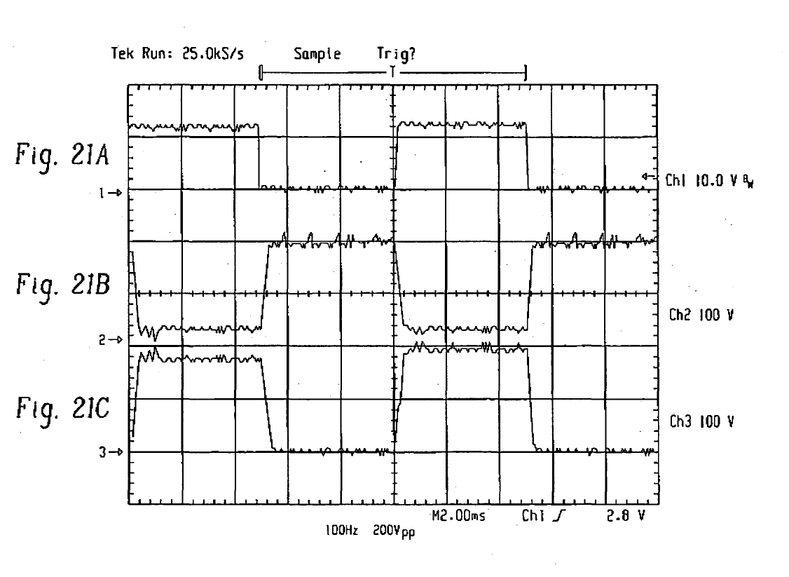

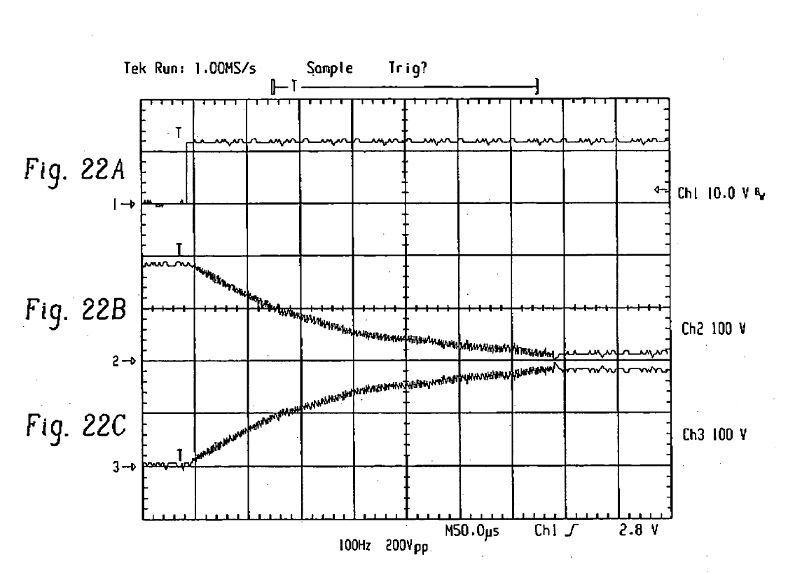

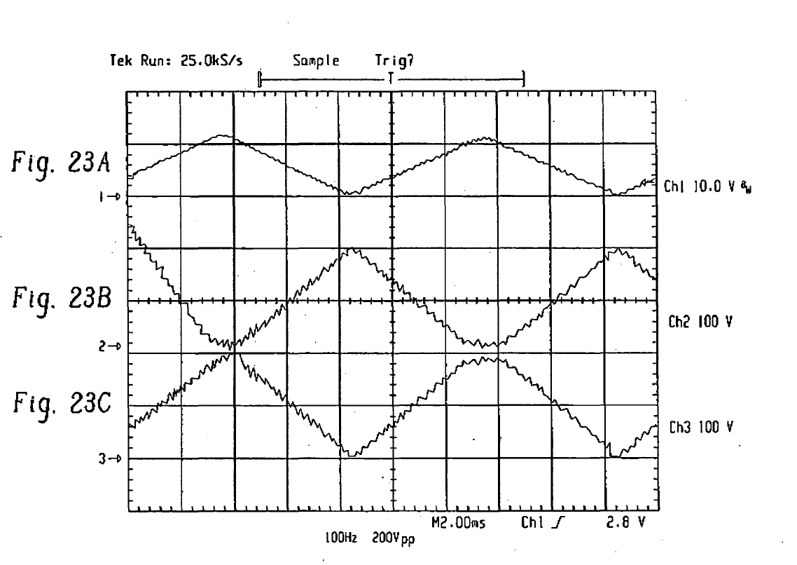

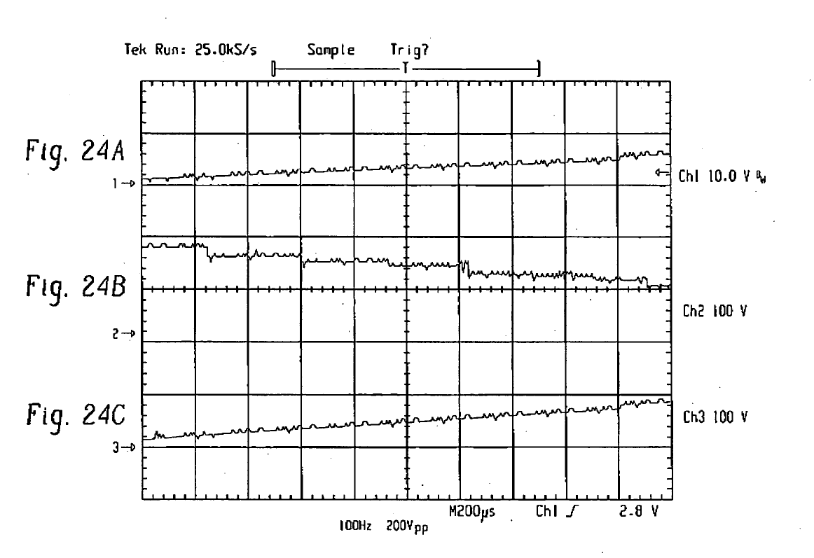

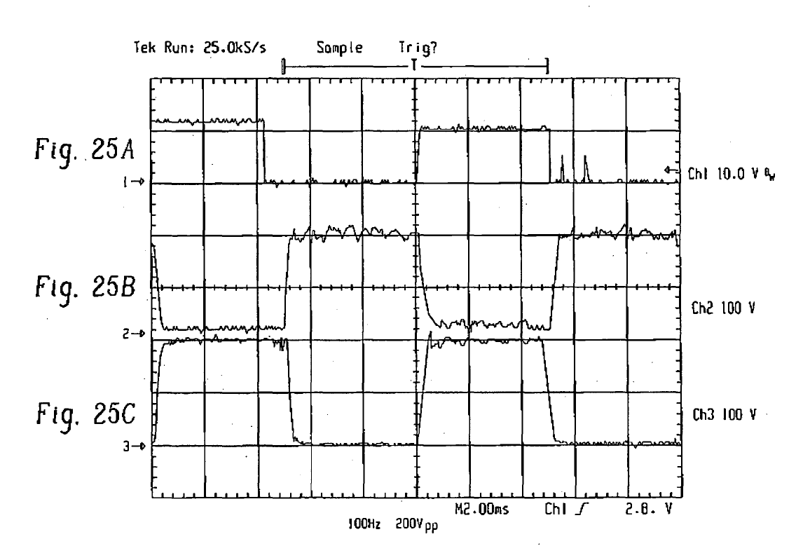

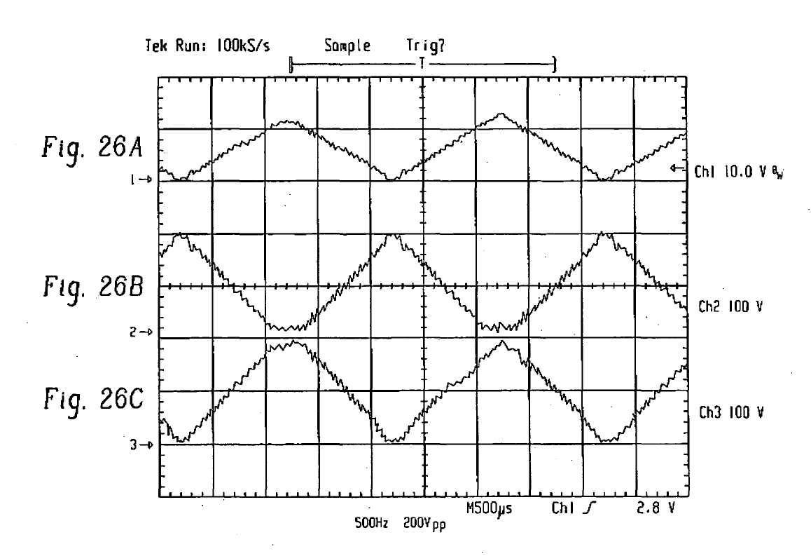

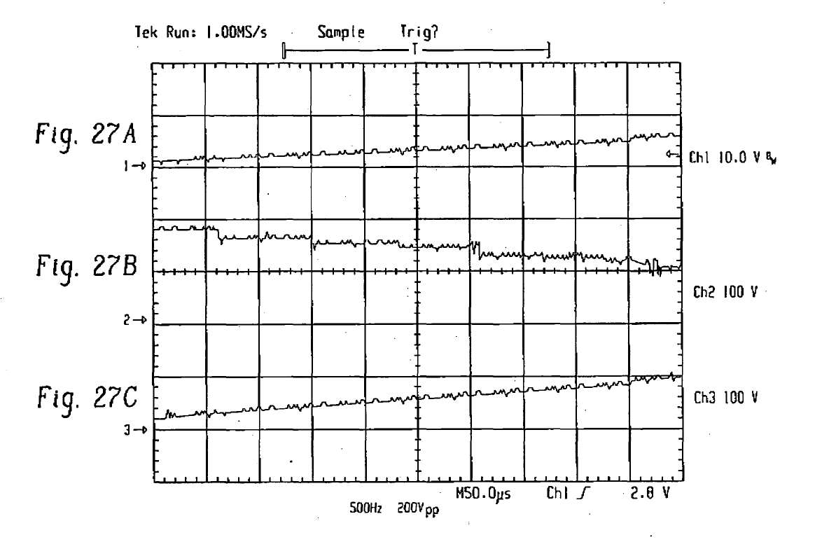

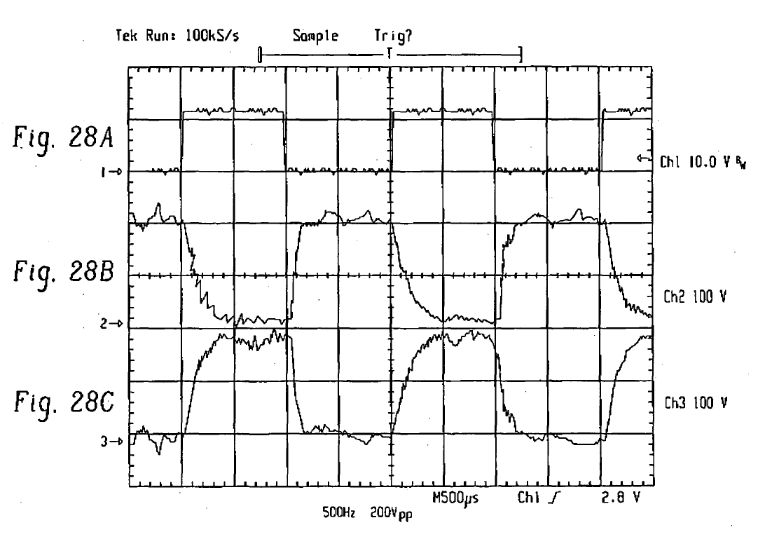

This is exemplified by the waveforms of FIGS. 15-28, which show two piezoelectric driver outputs of the type of driver circuit of FIGS. 4A-4I in circuit communication with piezoelectric actuators (a dual channel embodiment is described below in the text accompanying FIGS. 9 and 10), responsive to various input signals. In these figures, the proportional control input signal is shown in the “A” figure (FIG. 15A, FIG. 16A, etc.) and the two piezoelectric driver outputs are shown in the “B” figure (FIG. 15B, FIG. 16B, etc.) and “C” figure (FIG. 15C, FIG. 16C, etc.). The square wave input signal shown in FIGS. 15A and 16A is driving the respective output signals (FIGS. 15B and 15C and FIGS. 16B and 16C) to about 50 volts peak-to-peak at about 100 Hertz. As the 50 μs scale of FIGS. 16B and 16C indicates, the driver signals rise (about 0 to about 50 Vₚₚ) and fall (about 50 Vₚₚ to about 0 Vₚₚ) in about 50 μs. The square wave input signal shown in FIGS. 17A and 18A is driving the respective output signals (FIGS. 17B and 17C and FIGS. 18B and 18C) to about 100 volts peak-to-peak at about 100 Hertz. As the 50 μs scale of FIGS. 18B and 18C indicates, the driver signals rise (about 0 to about 100 Vₚₚ) and fall (about 100 Vₚₚ to about 0 Vₚₚ) in about 100 μs. The square wave input signal shown in FIGS. 19A and 20A is driving the respective output signals (FIGS. 19B and 19C and FIGS. 20B and 20C) to about 150 volts peak-to-peak at about 100 Hertz. As the 50 μs scale of FIGS. 20B and 20C indicates, the driver signals rise (about 0 to about 150 Vₚₚ) and fall (about 150 Vₚₚ to about 0 Vₚₚ) in about 175 μs. The square wave input signal shown in FIGS. 21A and 22A is driving the respective output signals (FIGS. 21B and 21C and FIGS. 22B and 22C) to about 200 volts peak-to-peak at about 100 Hertz. As the 50 μs scale of FIGS. 22B and 22C indicates, the driver signals rise (about 0 to about 200 Vₚₚ) and fall (about 200 Vₚₚ to about 0 Vₚₚ) in about 300 μs. The triangle wave input signal shown in FIGS. 23A and 24A is driving the respective output signals (FIGS. 23B and 23C and FIGS. 24B and 24C) to about 200 volts peak-to-peak at about 100 Hertz. Although the waveforms of FIGS. 23B and 23C are generally proportional to the input of FIG. 23A, a comparison of the waveforms of FIGS. 24B and 24C at a 200 μs scale shows the step-wise decreasing of the discharging signal of FIG. 24B, discussed above. FIGS. 26A-26C and 27A-27C show a similar effect at 500 Hertz. A comparison of FIGS. 25A-25C and 28A-28C shows the difference made by inputting square waves at different frequencies that drive the outputs to about 200 volts peak-to-peak: the outputs are generally proportional to the inputs, with more distortion at 500 Hertz than at 100 Hertz.

The circuit in FIGS. 4A-4I implements a switch-mode power converter that achieves significant efficiency improvements over linear amplifier techniques. Measured AC power consumption of the circuit with 200 volt square-wave outputs to piezoelectric actuators show that the circuit consumes about 5 watts per channel while delivering about 35 watts per channel at 700 Hz. Thus, the circuit dissipates about one-seventh of the power delivered to the high-capacitance piezoelectric load, which is a power dissipation of much less than half, much less than one-third, of the power delivered to the load. This is a significant improvement over typical linear techniques. That said, limitations in the present thermal design of the actuators restrict operation to at or below 700 Hz, which frequency might be increased by adding cooling means to the actuator(s), e.g., one or more or the following: fans and/or heat sinks and/or cooling systems, etc.

Generally speaking, in mapping the corresponding elements of FIGS. 4A-4I onto FIGS. 1-3, FIGS. 4A-4C show the power supply 24, FIGS. 4D and 4E show the power circuit 22, and FIGS. 4F-4I show the control circuit 20. To aid in understanding the mapping between the circuitry of FIG. 3 and the circuitry in FIGS. 4A-4I, FIG. 3B presents some of the circuitry shown in FIG. 3 repositioned to be in roughly the same position in the mosaic of FIGS. 4A-4I. With reference to FIG. 4D, capacitor C88 corresponds to capacitor 40 in FIG. 3A, transformer T1 corresponds to transformer 42 in FIG. 3A, transistor switch Q1 corresponds to primary switch 44 in FIG. 3A, driver chip U2 and associated components correspond to driver circuit 48 in FIG. 3A, and transformer T4 and associated circuitry correspond to primary current sense 60 in FIG. 3A. With reference to FIG. 4E, transistor switch Q2 corresponds to secondary side switch 54 in FIG. 3A, resistor 124, amplifier U8C, and associated components correspond to secondary current sense 64 in FIG. 3A, and the voltage divider formed by resistors R2 and R3 correspond to voltage sense 70 in FIG. 3A. With reference to FIG. 4F, most of this figure corresponds to the signal conditioning circuit 90 or the setpoint/feedback circuit 88 in FIG. 3A. With reference to FIG. 4G, amplifier U8A and associated components correspond to charge/discharge circuit 84 in FIG. 3A. With reference to FIG. 4H, primary control chip U11 and associated components correspond to primary control circuit 80 in FIG. 3A. With reference to FIG. 4I, secondary control chip U12 and associated components correspond to secondary control circuit 82 in FIG. 3A. Some of the circuitry in figures, e.g., diodes D14 and D35 in FIG. 4H, correspond to primary mode control circuit 86 in FIG. 3A.

Referring now to FIG. 4A, the power input section is shown. This implementation is designed to operate from a 120 VAC, 60 Hz power line, input at pins 1 and 2 of connector J1 of FIG. 4A, with pin 3 being connected to earth ground. It accommodates line voltage variations of +/−10% and a 50 to 60 Hz line frequency. A 1.5 amp normal-blow fuse F1 protects the circuit in the event of a component failure or a power supply short circuit. Choke L1 and its associated capacitors that connect to earth-ground (C94, C95, C97, C98) form a high-frequency common-mode filter that attenuates outgoing conducted emissions and incoming line noise. Leakage inductance resulting from the loosely coupled windings of L1 in combination with capacitors across the line (C3, C96) provides normal-mode filtering. Varistor MOV1 attenuates line-voltage spikes ahead of AC rectifier D1. The leakage inductance of L1 limits the spike currents in MOV1. The AC rectifier D1 is a conventional bridge circuit, except it preferably also includes an active in-rush current limiter, formed by power FET Q5 in conjunction with zener diode D17, source resistor R81, and resistor R80, which together limit the in-rush current to around 5 amps. Capacitors C4 and C5 form low and high frequency sections respectively of a bridge output reservoir. With a 120 VAC input to the bridge D1, the nominal output 28 is +160 VDC, unregulated. Bleeder resistor R133 provides a safe discharge for the reservoir capacitors C4 and C5 during a power-off interval.

Referring now to FIGS. 4B and 4C, the low voltage portion of power supply 24 is shown. The control circuitry 20 of the circuit is powered from +/−15 VDC rails. In the implementation of FIGS. 4A-4I, there are two +15 volt DC rails. One +15 volt DC rail 30a is referenced to the “hot” ground [symbol] symbol on the schematics). The other +15 volt DC rail 30b is referenced to system ground ( [symbol] symbol). A single −15 volt DC rail 30c is provided and is referenced to system ground. These three power supply voltages, along with their respective grounds, comprise low-voltage power supply outputs 30a-30c. It is believed that the circuitry of FIGS. 4A-4C could have been replaced with an appropriate “brick” type power supply, providing a relatively high-voltage output 28 and the low-voltage power supply outputs 30. In the specific implementation of FIGS. 4A-4I, linear regulators U16, U15 & U17 generate these three voltages 30a, 30b, and 30c respectively. Input power for the linear regulators comes from charge reservoir capacitors C11, C12, and C57 and ultra-fast half-wave rectifiers (D7, D10, D22), which are driven by three identical secondary windings T3a, T3b, and T3c on the power supply inductor T3. Inductor T3 is driven by control chip U4 (e.g., Power Integrations, Inc. P/N TOP204), a 3-terminal, off-line, pulse-width modulated (PWM) switch. Control chip U4 preferably operates at a nominal frequency of 100 kHz (i.e. 10 μsec period). In order to start up control chip U4, its control pin must first be ramped up to 5.7 volts. This is done with U4's internal current-source that charges up capacitor C9 from the +160 volt bus. The current source turns off when the capacitor reaches 5.7 volts and PWM operation commences.

The primary side T3d of inductor T3 is connected between the +160 volt supply and a power field-effect transistor (FET) within control chip U4. This FET is switched to ground at 100 kHz with a duty cycle that varies inversely with the current flowing into the control pin (1) of U4. When the FET internal to U4 is turned on, the primary current ramps up at a nominal rate of:

dIp/dt=V/Lp=(160 volts)/(706 μH)=227 mA/μsec

The secondary rectifiers D7, D22, and D10 are held reverse-biased, and energy is built up in the magnetic field of T3:

E=½*Lp*Ip² (a)

Except where cycle-to-cycle current limiting is required, chip U4 operates at its maximum cycle of 67% (i.e. FET on-time of 6.7 μsec) until the voltage control-loop closes back to its control-pin (1).

During the first PWM cycle, primary current ramps up to:

Ip(peak)=227 mA/μsec*6.7 μsec=1.52 amps. (b)

When chip U4 turns off, the magnetic field of inductor T3 begins to collapse, and rectifiers D7, D9, D10, and D22 are forward biased. Thus, energy is transferred from the energy in T3 to the secondary loads, U15, U16, and U17. Given the 8:1 turns-ratio between the primary T3d and each secondary T3a-T3c, the initial secondary peak current (total for all windings) is:

Is(peak total)=8*1.52 amps =12.2 amps (i)

Most of this current is split into three equal currents that charge reservoir capacitors C11, C12, and C57. A small fraction of this current (limited by resistor R17) begins to charge feedback capacitors C10 and C62.

During this first cycle, the only significant voltage bucking the secondary currents are the rectifier forward voltages (approx. 1.7 volts at 4 amps). While U4 is off, the diode voltage causes the total secondary current to ramp down by:

ΔIs=V*Δt/Ls=(1.7 V*3.3 μsec)/(706 μH/64)=0.5 amps

(i.e. the secondary current ramps down from 12.2 amps to 11.7 amps). At the end of the first PWM cycle, C11, C12 and C57 charge to approximately:

ΔV=Is*Δt/C=12.2*3.3 μsec/(3*47 μF)=0.3 volts

Because the magnetic field in transformer T3 does not collapse to zero before the beginning of the second PWM cycle, the power supply 24 is operating in a continuous-conduction energy storage mode. This mode of operation maximizes the charging rate of the reservoir capacitors C11, C12, and C57.

During the second PWM cycle, the primary current starts ramp-up at:

11.7 amps/8=1.46 amps.

Shortly thereafter (approximately 3.5 μsec later), the primary current reaches the 2.25 amp self-protection current-limit of U4, and the duty-cycle is terminated early. U4 continues to operate in this current-controlled continuous-conduction (CCCC) mode until sufficient voltage is established on capacitor C10 to close the feedback path to the control pin (1) of chip U4. At this time the PWM duty-cycle is reduced by U4 so that the power delivered to the magnetic field of transformer T3 while chip U4 is on, is balanced by the power requirements of the secondary loads (neglecting transformer and transistor losses). In doing so, the switching supply transitions to a voltage-controlled discontinuous-conduction (VCDC) mode.

Capacitor C10 receives its charge from a fourth secondary winding T3e of inductor T3. Since all four secondary windings T3a-T3c and T3e have identical 10-turn windings and are tightly coupled, the four voltage waveforms in each secondary winding are essentially identical, and the voltage on capacitor C10 tracks the voltage on capacitors C11, C12, and C57. Following its initial start-up charging, the voltage on capacitor C9 is still close to 5.7 volts. When the voltage on capacitor C10 reaches about 21 volts there is sufficient voltage turn on the base-emitter junction of transistor Q9 (through voltage divider formed by resistors R153 and R155) and to cause the 15 volt zener diode D8 to break down. At this point the feedback loop is closed around chip U4 and the power-supply transitions to a voltage-controlled mode. The dynamic conductance of the feedback path is approximately 29 mA/volt (i.e. reciprocal of R17).

The steady-state duty-cycle for chip U4 and the corresponding currents in inductor T3 can be estimated from the total power output requirements of the power supply 24. For example, assuming a 10 watt load on each of the three 15 volt supplies (i.e. 30 watts total), each PWM cycle is required to deliver the following energy:

(30 watts)/(100,000 Hz)=300 μJ

With Lp=706 μH, the required peak primary current is:

Ip={square root over ([(300 μJ)/(½)}*706 μH)]=0.92 amps

Thus, with a 160 VDC power source, U4 reaches this level of current in:

0.92 amps/(0.227 amps/μsec)=4.1/μsec,

resulting in a steady-state PWM duty-cycle of 41%. With 21 volt secondary load potentials, the total secondary current starts at:

Is(peak total)=8*0.92 amps=7.36 amps, (ii)

and ramps to zero value in:

Δt=Ls*ΔI/Vc=(706 μH/64)*(7.36 amps)/(21 volts)=3.7 μsec.

In this example, the “on time” is 4.1 μsec, the “off time” is 3.7 μsec, and the “dwell time” (where neither primary nor secondary currents flow) is 2.2 μsec. The sum of these three times is the period of the PWM switching cycle (10 μsec).

Zener diode D5 (220 volts) and ultra-fast rectifier D6 safely dissipate the energy built up in the leakage inductance of T3 during each switching cycle.

In the event of a line-voltage “brown-out,” the low-voltage circuitry of FIGS. 4B and 4C is shutdown by a Maxim MAX8211 voltage detector, U18. The MAX8211 voltage detector U18 obtains its power from zener diode D67 (5.1 volts) (and resistor R150 and capacitor CPP) while the threshold pin (3) monitors the +160 VDC supply via the voltage divider formed by R151 and R152, along with capacitor C100. When the voltage at threshold pin (3) of U18 is above 1.15 volts, the hysteresis pin (2) of U18 is internally switched to V+(5.1 volts) and the output pin (4) is an open circuit. When the voltage at threshold pin (3) of U18 drops below 1.15 volts, the hysteresis pin (2) open circuits and a 7 mA current-source at the output pin (4) pulls to ground. This has the effect of discharging capacitor C9 via resistor R155, which is attached to the control pin (1) of control chip U4. Control chip U4 will turn off when its control pin (1) voltage drops below 4.7 volts. Resistor R154 provides positive feedback to the +160 VDC voltage divider formed by R151 and R152 and adds hysteresis to the line-voltage on-off threshold. Under minimum load (i.e. actuator output voltages are static), U18 shuts down the auxiliary power supply when the AC line voltage (at pins 1 and 2 of J1 in FIG. 4A) drops below about 70 VAC. U18 will permit the power supply 24 to turn back on again when the AC line voltage returns to about 100 VAC. At full-load (i.e. actuator output voltages are changing rapidly), the shut-down and turn-on AC line voltages are about 85 and about 100 VAC, respectively.

Referring now to FIGS. 4D and 4E, the power circuit 22 (one-channel) is shown. The circuit 22 of FIGS. 4D and 4E is designed to drive a CeramTec monolithic multi-layer actuator 12, which utilize the piezoelectric effect, e.g., (1) Hoechst Ceramtec AG, Piezoceramics Product Group having dimensions of 30 mm×5 mm×5 mm (model number 39999-34.3) or (2) Part No. 20B available from Sumitomo. Electrically these actuators need to be protected against over-voltage (e.g., protected from voltages greater than 250 volts DC), short-circuits, and reverse-bias. The electrical equivalent circuit of these actuators is a complex function of both excitation voltage and excitation frequency. When driven with a 200 volt peak-to-peak square-wave at 1000 Hz, the Hoechst actuator is approximately electrically equivalent to a 2.5 μF capacitor in parallel with a 2-4 kΩ resistor. Additional losses are modeled by a 4 Ω resistance in series with the parallel components.

In FIGS. 4D and 4E the voltage 14 controlling the piezoelectric actuator 12 is output at connector J2. This control voltage tracks the input signal 32, which is input at connector J4. A 0 to +12 volt input at J4 creates an amplified, proportional 0 to +200 volt output (voltage gain of 16.667) at J4 to the piezoelectric actuator 12. The circuit of FIGS. 4A-4I is optimized for fast on-off control of actuators 12. Additionally, it can also deliver analog output waveforms. Output amplitudes are proportional to the signal input, while the bandwidth and “smoothness” of output waveforms is essentially limited only by the switching frequency of the switch-mode amplifier.

In the implementation of FIGS. 4A-4I, a fly-back inductor T1 generates the output at J2 under the control of a pair of power Metal-Oxide Semiconductor Field-Effect Transistors (MOSFETs) acting as switches: primary side MOSFET switch Q1 and secondary side MOSFET switch Q2. Inductor T1 shuttles energy between the +160 volt bus and J2 (to the piezoelectric actuator 12), while switches Q1 and Q2 control the direction of energy transfer. When the piezoelectric actuator 12 at J2 is being charged, primary side switch Q1 is in a pulse-width modulated mode and secondary side switch Q2 remains turned off. When the piezoelectric actuator is being discharged, secondary side switch Q2 is pulse-width modulated and primary side switch Q1 remains turned off. When either MOSFET Q1 or Q2 is turned on, current ramps up in its corresponding inductor primary winding, and magnetic energy is built up in the core of inductor T1. When this MOSFET turns off, the magnetic field collapses and electrical energy is delivered to the half-wave rectifier on the secondary side of the inductor. On either side, the rectifier is the intrinsic drain-source diode of the corresponding MOSFET Q1 or Q2. Unlike the intrinsic diodes in most power MOSFETs, the diodes of these particular MOSFETs (IXYS part number IRFPC40) are fast-recovery devices suited for high-frequency rectification. Zener diodes D41, D42 and ultra-fast rectifiers D19, D40 across the primary and secondary windings of inductor T1, respectively, attenuate leakage inductance voltage transients. Gate resistors R143 and R126 limit the load currents delivered from opto-isolated power driver U2 to primary side switch Q1 and from PWM driver U12 (FIG. 4I) to secondary side switch Q2, respectively. Schottky diodes D53 and D51 speed up the tum-off of the switches Q1 and Q2.

Referring now to FIGS. 4F-4I, the control circuitry 20 is shown. Referring specifically to FIG. 4F, a proportional control signal 32 enters at connector J4. This control signal 32 is conditioned by resistors R92, R132, R134, capacitor C107, and Zener diode D49. Operational amplifier U7A and associated resistor R24, resistor R25, capacitor C106, and potentiometer R156 implement an inverting amplifier that provides full scale adjustment, offset, and adjusts the overall input gain with respect to the input signal 32. Zener diode D38, resistor R103, and capacitor C75 generate a −1.23 VDC reference voltage for inverter U7A and other circuitry. Operational amplifier U7B is a buffer (voltage follower) that follows a voltage proportional to the actuator voltage 14 via a voltage divider created by resistors R2 and R3 (FIG. 4E). Operational amplifier U7C and associated resistors R27, R28, and R30 and capacitor R30 implement an inverting summing amplifier. Inverting summing amplifier U7C provides a signal proportional to a weighted sum of the outputs of inverter U7A setpoint and buffer U7B voltage feedback.

Referring now to FIG. 4G, operational amplifier U7D and associated components resistors R31, R98, R99, and R100 and capacitor C21 implement a scaling amplifier (scaler) having an offset created by resistors R99 and R100. Scaler U7D accepts the output of inverting summer U7C and generates a control signal that controls primary side control chip U11. To prevent damage to U11, diodes D33 and D34 clamp U7D within a diode drop between U11's V_{ref} voltage and ground. Operational amplifier U8A and associated resistors R29, R39, R104 and R105 and capacitor C77 implement a charge/discharge comparator. Charge/discharge comparator U8A accepts the output of inverting summer U7C and generates a square wave control signal that switches U12 on for discharging and off for charging. Operational amplifier U8B and associated resistors R41 and R42 and capacitor C27 implement a unity-gain, inverting buffer (with bandwidth limiting). Inverting buffer U8B accepts the output from charge/discharge comparator U8A and switches U11 on for charging and off for discharging.

FIG. 4H shows the primary side control chip U11 and associated components, which are described below. Resistors R47 and R102 facilitate switching U11 off for discharge mode and on for charge mode. Diode D14 blocks current in the charge mode so that the VCC1 signal controls current limiting. Similarly, FIG. 4I shows the secondary mode control chip U12 and associated components, many of which are described below. As discussed in more detail below, primary side control chip U11 controls the charging of the actuator 12 and secondary mode control chip U12 controls the discharging of the actuator 12.

The circuitry of FIGS. 4A-4I can be thought of in two modes with respect to the piezoelectric actuator: the piezoelectric actuator charging and the piezoelectric actuator discharging. The primary side switch Q1 acts as a charge transistor and the secondary side switch Q2 acts as a discharge transistor.

The first mode, the piezoelectric actuator charging mode, will be discussed first. The charge transistor Q1 (i.e., primary side switch Q1) receives its PWM control from primary side control chip U11 (FIG. 4H) (Unitrode Part Number UC3845A), a current-mode controller. Because switch Q1 connects to “hot” ground, the PWM output from primary side control chip U11 is opto-coupled to switch Q1 by optoisolated power driver U2 (Toshiba Part Number TLP250).

There are two feedback loops returning to primary side control chip U11. During “pump-up” of the actuator voltage 14, the fly-back transformer current is limited via feedback to the Isense pin (3) of primary side control chip U11. A 1 volt level on this pin (3) resets the current PWM cycle. Current transformer T4 provides electrical isolation in this path. When the actuator 12 reaches its set-point voltage, control of the PWM duty cycle is taken over by an error amplifier within primary side control chip U11. The Comp pin (1) and Vfb pin (2) of primary side control chip U11 connect to this amplifier and provide the voltage control function.

Components R38 and C23 set the clock frequency of primary side control chip U11 at 340 kHz. An 8.3 mA current sink within primary side control chip U11 discharges capacitor C23 when its voltage exceeds 2.8 volts. The current sink turns off when the voltage at capacitor C23 drops below 1.1 volts. An on-chip T flip-flop sets the PWM frequency at half the clock frequency (170 kHz). The duty-cycle of the internal clock and the T flip-flop limit the maximum PWM duty cycle to 45%.

During actuator “pump-up,” the driver 10 of FIGS. 4D-4I operates so as to maximize the rate of energy transfer from capacitor 40 to actuator 12. The PWM duty-cycle is limited only to keep inductor T1 out of saturation, i.e., to keep the current through inductor T1 low enough that it does not saturate. During this current-controlled mode of operation there are two energy storage phases: current-controlled continuous-conduction (CCCC) and current-controlled discontinuous-conduction (CCDC). The CCCC phase is when the actuator voltage is below about 130 volts. At this voltage level the actuator voltage is insufficient to drive the secondary current back to zero before the start of the next PWM cycle (i.e. the magnetic field of inductor T1 does not return to zero between successive PWM cycles). As the actuator voltage 14 rises to about 130 VDC, the driver 10 changes to the CCDC mode. During this interval the magnetic field of inductor T1 collapses to zero between PWM cycles, and the primary current ramps up from zero each time switch Q1 is turned on.

The nominal primary inductance (Lp) of inductor T1 is 42 μH. When switch Q1 is turned on, the +160V supply ramps up the primary current of T1 at:

dIp/dt=V/Lp=(160 volts)/(42 μH)=3.8 A/μsec.

The source current of switch Q1 (i.e. the primary current of inductor T1) is sensed by current transformer T4. Transformer T4 has a 1:200 turns-ratio. Thus, for each ampere of source current through switch Q1, 5 mA is delivered to resistor R144, resulting in an open-circuit voltage of approximately 0.21 volts at schematic node CC1 (FIG. 4D). As primary current ramps up in inductor T1, the voltage at CC1 (V_{CC1}) slews up at about 0.80 volts/μsec. Node CC1 connects via diode D35 to the Isense pin (3) of primary side control chip U11. Diode D14 also connects to the Isense pin (3) but it remains reverse biased during charging of actuator 12. In addition, emitter-follower formed by transistor Q6 buffers the 1.1 to 2.8 volt, 90% duty-cycle, clock saw-tooth signal at pin 4 of primary side control chip U11, and superimposes a 0.2 to 0.9 volt ramp on the Isense input pin (3) with a slew rate of 0.26 volts/μsec. If there is insufficient voltage at node CC1 to turn on diode D35, primary side control chip U11 runs at its maximum PWM duty-cycle of 45%. However, V_{CC1} slews faster than the clock derived ramp at pin 4. Thus, when the voltage differential is sufficient to turn on diode D35, the signals combine and ramp up at 0.40 volts/μsec toward the 1 volt reset level of primary side control chip U11.

During the first PWM cycle of charging, the voltage at CC1 turns on diode D35 after about 1.50 μsec. Consequently, switch Q1 is turned off after 2.35 μsec with a corresponding inductor T1 primary current of 9 amps (i.e. 1700 μJ of magnetic energy). Since the PWM period is about 5.88 μsec (PWM frequency of 170 kHz), this leaves 3.53 μsec for transfer of energy to the actuator. When switch Q1 is turned off by primary side control chip U11, the intrinsic diode of switch Q2 conducts. The secondary inductance of T1 (Ls=42 μH) and the actuator-capacitance (Ca=2.5 μF) form an LC tank circuit having a resonant frequency of:

fr=1/[2*π*\sqrt{(Ls*Ca)}]=15.5 kHz. (c)

This tank circuit has an initial inductor current (Ii) of 9 amps and an initial actuator voltage of zero. In the 3.53 μsec duration available energy transfer, the secondary current decreases to:

If=(9 amps)*cos (2*π*fr*3.53 μsec)=8.5 amps (d)

The corresponding decrease of inductive energy is:

ΔE=½*Ls*(Ii²−If₂)=184 μJ,

while the actuator voltage is raised to:

ΔV={square root over ((2*ΔE/Ca)}=12 volts

When Q1 is turned on for its second PWM cycle, the secondary current of T1 drops to zero and the primary current of T1 immediately jumps to 8.5 amps and V_{CC1} starts at 1.76 volts. The resulting voltage across R101 is approximately 0.63 volts and is high enough initially to keep Q6 turned off. The input to Isense ramps past 1 volt after approximately 0.76 μsec, turning off Q1 after setting up a primary current of 11 amps. These calculations can be reiterated from cycle to cycle in order to determine the current swings, timing and energy transfers of subsequent CCCC PWM cycles.

As the driver voltage 14 reaches approximately 130 volts DC (for a 12 VDC input signal), the CCDC mode is entered. Once the CCDC mode is entered, the primary currents and timing of each PWM cycle are a repetition of those obtained on the first CCCC cycle. The secondary currents return to zero between cycles resulting in full cycle-to-cycle transfer of magnetic energy from T1 to the actuator.

As the actuator voltage 14 reaches its setpoint, the driver settles into a voltage-controlled discontinuous-conduction (VCDC) mode. At this point a voltage loop takes over control of the PWM duty-cycle and regulates the actuator voltage 14.

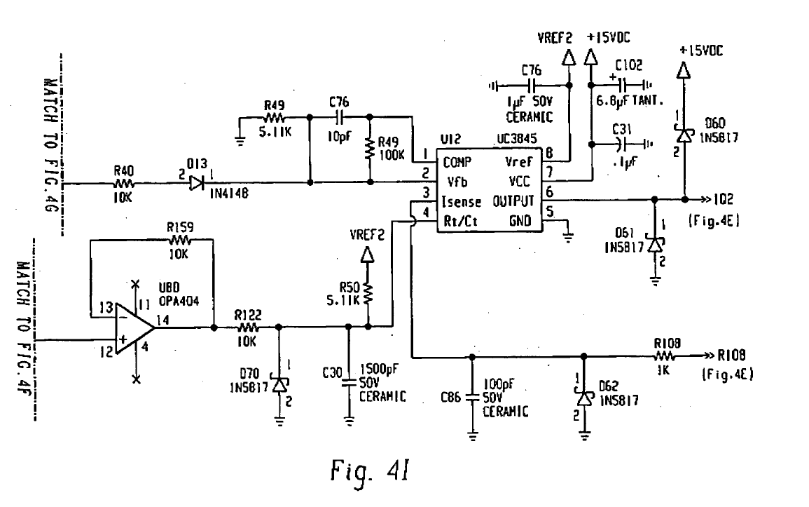

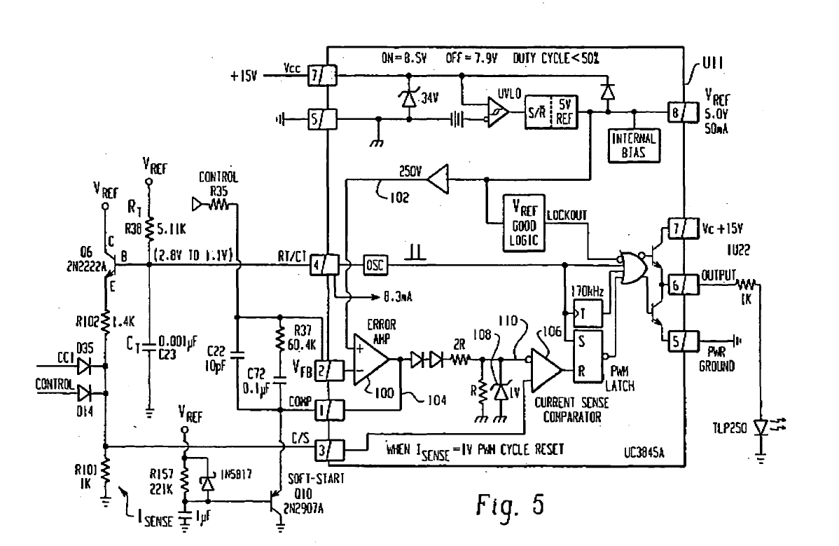

FIG. 5 shows an internal schematic diagram of primary side control chip U11 with some of the associated components of FIGS. 4D-4I affecting primary side control chip U11. Within primary side control chip U11 there is an error amplifier (i.e. operational amplifier) 100 with an internal +2.5 volt reference 102 applied to its non-inverting input. Components R35 (FIG. 4G) and R37, C72 and C22 (FIG. 4H) configure the internal amplifier 100 essentially as an integrator with lead-compensation. The error-amplifier input voltage (2) is provided via resistor R35 and is a linear, weighted summation of the actuator setpoint signal (input signal 32 input at J4), an actuator voltage feedback signal 72 (from a voltage divider created by resistors R2 and R3 in series across the actuator voltage 14) and miscellaneous offsets. These signals are discussed further below.

While the actuator voltage 14 is increasing, i.e., being “pumped up,” the error-amplifier input (2) of primary side control chip U11 is less than +2.5 volts, causing the error-amplifier output 104 to ramp positive. This output is internally diode clamped to +1 volt at the inverting-input of current sense comparator 106 by internal Zener diode 108 (this +1 volt reset level is active during CCCC and CCDC operation).

As the actuator voltage 14 approaches its set-point, the error-amplifier input (2) approaches +2.5 volts and the output 104 of the error-amplifier 100 (FIG. 5) starts to ramp down. This results in a reduction of the reset voltage 110 of the current-sense comparator 106 and early termination of the PWM cycle. Once the actuator voltage 14 is at its set-point, the reset voltage 110 is essentially zero. The clock-derived ramp is still applied to the Isense pin (3) of primary side control chip U11, but the resulting PWM duty-cycle is zero because the reset voltage 110 is essentially zero.

Transistor Q10 and associated components Zener diode D69, resistor R157, and capacitor C101 (FIGS. 4H and 5) provide a soft-start for primary side control chip U11 during initial power-up. The error-amplifier output source current is internally limited to 0.5 mA. While capacitor C101 is being charged by resistor R157 (221 msec time-constant), the error-amplifier output 104 is pulled down and the PWM duty-cycles are terminated early.

At the end of the actuator voltage charge phase, the output of the charge-discharge detector U8A switches from +13 volts (+saturation) to −14 volts (−saturation). The inverted waveform at the output of U8B turns on D14 and applies +1.9 volts to the Isense pin (3) of primary side control chip U11. This ensures that the charge PWM is disabled during actuator discharge.

The process of discharging the actuator 12 capacitance is similar to that of charging it. Primary switch Q1 is turned off while secondary switch Q2 is pulse-width modulated by current-mode controller (secondary mode control chip) U12. When switch Q2 is turned on, the actuator voltage 14 ramps up the current in the secondary T1b of inductor T1. Switch Q2 is turned off when the secondary current reaches 10 amps or when the PWM duty-cycle times out at 45%, whichever comes first. When the secondary current is interrupted by switch Q2 being turned off, the magnetic field of inductor T1 begins to collapse, inducing an equal current in the primary winding T1a that flows back to the +160 volt reservoir capacitor C88. The intrinsic drain-source diode of transistor Q1 serves as a high-speed half-wave rectifier. As PWM cycles are repeated, the voltage of the actuator capacitance is reduced to zero value, and the associated capacitive energy, minus ohmic and core losses, is returned to the power supply reservoir capacitor C88.

The 10 amp current limit of the secondary winding T1b is set by the 0.1 Ω current-shunt resistor R124. The voltage-drop across resistor R124 is measured by a unity-gain differential amplifier U8C, and forwarded to the Isense pin (3) of secondary mode control chip U12. Resistor R108 and capacitor C86 serve as a transient filter, while Zener diode D62 clamps below-ground inputs to the Isense pin.

The charge and discharge phases differ as follows. During actuator charging, energy is obtained from a constant-voltage source (+160 volt supply and associated capacitor C88) and delivered to a charging capacitor (i.e. actuator 12). During charging, the primary-current ramp-up rate is a constant (3.8 Amps/μsec). During discharge, energy is obtained from a discharging capacitor (i.e. actuator 12), and returned to the constant-voltage source (+160 volt supply and associated capacitor C88). The secondary current ramp-up rate declines in proportion to the remaining actuator voltage.

In order to increase the rate of energy transfer from the actuator 12 back to the power supply and capacitor C88, the PWM clock frequency is reduced as the actuator is discharged. The principle behind this frequency modulation can be explained as follows: during actuator discharge, reducing the clock frequency frequency allows the secondary current to increase before termination of that PWM cycle (assuming that the current-limit is not tripped), which has the effect of greatly increasing the peak energy in the magnetic field of T1 during that PWM cycle (thus, even though the frequency is reduced, there is a net increase of the energy transfer rate). Numerically, because E=½Li², reducing the frequency of the PWM clock to one-half of its original frequency allows the secondary current to double (×2) before termination of that PWM cycle (assuming that the 10 amp current-limit is not tripped), which has the effect or quadrupling (22=4) the peak energy in the magnetic field of T1 during that PWM cycle. Thus, even though the frequency is halved, there is a net doubling (×2) of the energy transfer rate: twice the energy is transferred in the same amount of time by reducing the PWM frequency. In the circuit of FIGS. 4A-4I, the PWM clock frequency of secondary mode control chip U12 is sequentially reduced as the actuator 12 is discharged.

Frequency modulation of the discharge PWM clock of secondary mode control chip U12 is accomplished by connecting resistor R122 to the clock-timing node (pin 4) of secondary mode control chip U12. Resistor R122 delivers a current proportional to the actuator voltage via voltage follower U8D and voltage follower U7B. At the beginning of actuator discharge, the actuator 12 is at 200 volts for a 12 volt input signal and USD applies 6.1 volts to resistor R122. The calculated clock frequency of U12 is approximately 350 kHz, resulting in a discharge PWM frequency of 175 kHz. With 100 volts and 0 volts on the actuator, the respective PWM frequencies are 127 kHz and 78 kHz respectively. Using these frequencies, sample PWM cycles can be quantified as follows.

When secondary transistor switch Q2 turns on, it connects the secondary inductance (42 μH, from secondary T1b) across the inherent actuator capacitance (2.5 μF) to form a parallel tank circuit. This tank circuit has a resonant frequency of approximately 15.5 kHz (i.e. approximately 64.4 μsec period). At the start of the first PWM discharge-cycle, the initial inductor current is zero, and the initial capacitor voltage is 200 volts. The actuator voltage discharges as follows:

Va(t)=(200 volts)*cos(2*π*fr*t) (e)

while the secondary current ramps up:

Is(t)=(200 volts)*\sqrt{(Ca/Ls)}*sin(2π*fr*t) (f)

The secondary current reaches the 10 amp limit after:

t=(½*π*fr)*arcsin [10 amp/(200 volt*\sqrt{(Ca/Ls)]}=2.1 μsec.

i.e. secondary switch Q2 is turned off prior to the 2.57 μsec PWM time-out at 45% duty-cycle.

Following the turn off of switch Q2, the primary current ramps down from 10 amps to zero amps at 4.89 μsec after the start of the PWM cycle. Since the period of the PWM signal is greater (1/175 kHz=5.72 μsec), this indicates a CCDC cycle. During this first cycle, the net energy (ideal) returned back to the power supply and capacitor C88 is:

ΔE=½*Ls*(10 amps)²=2.1 mJ,

while the actuator voltage is reduced by;

ΔV=ΔE/(Ca*Va)=4.2 volts.

At the mid-point of discharge (100 volts remaining on the actuator, PWM frequency=127 kHz), a typical PWM cycle ramps the secondary current up to 8.3 amps and drops the actuator voltage by 34 volts. These calculations can be reiterated cycle after cycle to quantify the discharge of the energy in the actuator capacitance.

During actuator discharge, the charge-discharge detector (comparator) U8A saturates at −14 volts, keeping D13 reverse-biased. In response to this, the error-amplifier of secondary mode control chip U12 saturates positive and holds the Isense threshold at 1 volt. When the next charge cycles returns, charge-discharge detector U8A saturates at +13 volts, and D13 conducts. In response, the secondary mode control chip U12 error amplifier saturates low, and the discharge PWM waveform is disabled.

With this overview, the control of actuator charging with the circuit of FIGS. 4D-4I will be discussed in further detail.

Before charging, the proportional control input 32 at connector J4 is zero volts. A 0 to +200 volt charging cycle is started by the proportional control input 32 changing to +12 volts.

At the start of a 0 to +200 volt actuator charge, inverting summer U7C initially has inputs of −12.4 volts and 0 volts from inverter U7A and buffer U7B respectively. In response, inverting summer U7C slews into positive saturation (+13 volts) and the output of scaler amplifier U7D goes to +0.5 volts. Resistor R35 connects U7D to the summing node (pin 2) of the error amplifier 100 within primary side control chip U11. In attempting to maintain its summing node at 2.5 volts (set by a reference tied to the non-inverting input), the error amplifier 100 saturates positive and enables the current control PWM mode.

As the actuator capacitance voltage 14 increases, i.e., is “pumped up,” buffer U7B delivers an increasing positive current into the summing node of inverting summer U7C. This causes inverting summer U7C to come out of saturation and to start ramping down. In response, scaler amplifier U7D starts to ramp upward. As the output of scaler amplifier U7D approaches its steady-state value of +2.5 volts, the PWM driver shuts down (changes to a discharge mode). The corresponding steady-state output voltages of inverting summer U7C and buffer U7B are +1.1 volts and +6.1 volts respectively, for a steady-state actuator voltage of 200 volts.

The open-loop response of this voltage control loop was analyzed mathematically. With a load capacitance of 2.5 μF for the actuator plus capacitor C6 (0.22 μF), the calculated unity-gain bandwidth is 1.2 kHz with a phase margin of 84°. Under a no-load condition (i.e. C6 only), the unity-gain bandwidth is 12.7 kHz with a phase margin of 570.

Potentiometer R156 is a gain adjustment that calibrates the full-scale actuator voltage.

Charge/discharge comparator U8A functions as a non-inverting comparator that monitors the output of inverting summer U7C. It has a −2.1 volt trip-point and 100 mV of hysteresis. During actuator charge, the output of charge/discharge comparator U8A saturates at +13 volts and turns on diode D13. This, is turn, keeps the secondary mode control chip U12 turned off.

An actuator discharge cycle is started by the proportional control input 32 transitioning from +12 volts to 0 volts.

At the start of a +200 to 0 volt actuator discharge, inverting summer U7C initially has inputs of −3.0 volts and 6.2 volts from inverter U7A and buffer U7B respectively. In response, inverting summer U7C slews into negative saturation (−13 volts) and the output of U7D goes to +4.8 volts. The error amplifier 100 within primary side control chip U11 saturates low that control chip U11 is shutdown.

In response, charge/discharge comparator U8A saturates negative (−13 volts) and reverse biases diode D13. In response, the error amplifier within secondary mode control chip U12 saturates high and enables current-control PWM operation of chip U12. The output of charge/discharge comparator U8A is inverted by inverter U8B. The resulting +13 volt output from U8B turns on diode D14, ensuring quick turnoff of primary side control chip U11.

As the actuator capacitance voltage 14 is reduced, i.e., “pumped down,” buffer U7B delivers a decreasing positive current to the summing node of inverting summer U7C. This causes inverting summer U7C to come out of saturation and to start ramping up, while scaling amplifier U7D starts to ramp downward. As the actuator voltage 14 returns to zero, the output of buffer U7B goes to zero, inverting summer U7C climbs to −2.0 volts, and scaling amplifier U7D drops to +3.0 volts.

As described above, the discharge PWM signal is frequency modulated by the actuator voltage, with buffer-amplifier U7B providing the frequency control voltage. In the implementation of FIGS. 4D-4I, the secondary control chip U12 preferably functions in the CCCC mode only (that said, if the driver voltage 14 is initially very low, the secondary control chip U12 might function in the CCDC mode).

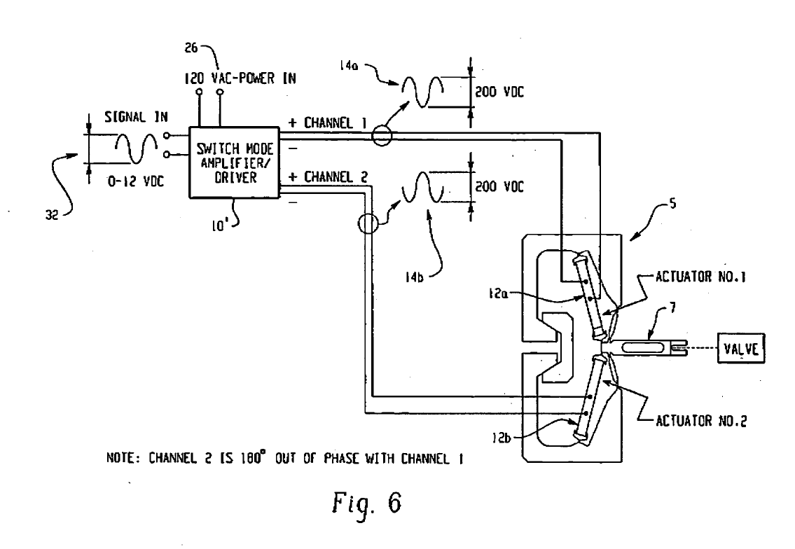

The driver 10 shown in FIGS. 1-5 is a single-channel driver circuit for driving, e.g., a single piezoelectric actuator. In the alternative, the driver circuit of the present invention can be used to drive multiple actuators, e.g., a pair of piezoelectric actuators housed in a mechanical amplifier, as taught in U.S. Pat. No. 6,157,115 (“the '115 patent”), which is assigned to the assignee of the present case. The '115 patent is hereby incorporated by reference in its entirety. FIG. 15 of the '115 patent, repeated as FIG. 6 herein, shows a general configuration of a two-channel driver suitable for driving the piezoelectric actuator pair disclosed in the '115 patent. Although the '115 patent states that “design of the amplifier 202 may be conventional,” the novel driver design according to the present invention is particularly well suited to drive a pair of piezoelectric actuators mounted as shown in the '115 patent.

With reference to FIG. 6, a two-channel driver 10′ according to the present invention drives a first piezoelectric actuator 12a and a second piezoelectric actuator 12b with first and second driver signals 14a, 14b, respectively, which are preferably 20 volt signals. The drive voltages are preferably proportional to and converted from a proportional control input signal 32, which is preferably a 12 volt signal. The actuators 12a, 12b are preferably mounted in a mechanical amplifier 5 and drive a valve 6 via an elongated displacement beam or bar 7, as taught in the '115 patent. The drive voltages 14a and 14b are preferably 180° out of phase with respect to each other; therefore the actuators 12a, 12b are preferably alternately driven. The '115 patent shows the use of sinusoidal signals to drive the actuators 12a, 12b. The driver according to the present invention can generate sinusoidal driving signals in response to a sinusoidal input signal. Additionally, the present invention is capable of generating square wave driving signals in response to a square wave input signal, capable of generating triangular driving signals in response to a triangular input signal, and is capable of generating virtually any shape of driving signal in response to a correspondingly-shaped input signal.

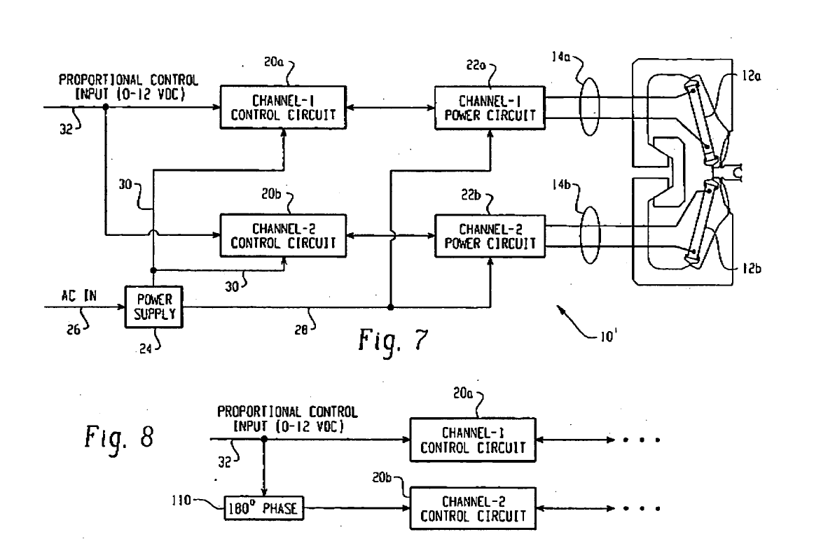

Referring now to FIG. 7, a block diagram of a two-channel driver 10′ according to the present invention is shown. The driver circuit 10′ in FIG. 7 is being used to drive a pair of actuators 12a, 12b, i.e., activate and deactivate actuators 12a, 12b, with a pair of driver signals 14a, 14b. Two-channel driver circuit 10′ of the present invention preferably comprises first and second control circuits 20a, 20b in circuit communication with respective power circuits 22a, 22b. As with the circuit shown in FIG. 1, practical considerations with respect to use of the driver circuit 10′ will likely require a power supply 24 accepting a power input 26, such as an AC input, to generate one or more suitable high-voltage DC signals 28 to be converted by the power circuits 22a, 22b under control of the control circuits 20a, 20b to activate loads 12a, 12b via driver signals 14a, 14b and also to generate one or more suitable low voltage signals 30 to power the circuitry making up the control circuits 20a, 20b, the power circuits 22a, 22b, and the power supply 24. The driver circuit 10 preferably accepts a control input 32 that controls the activation and deactivation of loads 12a, 12b by driver circuit 10′. The driver circuit 10′ more preferably accepts a proportional control input 32 that controls the activation and deactivation of loads 12a, 12b by driver circuit 10′, with one of the driver signals 14a, 14b being approximately proportional to the proportional control input signal 32 and the other driver signal being preferably 180° out of phase with respect thereto; therefore the actuators 12a, 12b are preferably alternately driven.

If the two actuators 12a, 12b are nominally the same, it is preferable to have the two control circuits 20a, 20b be identical circuits and the two power circuits 22a, 22b be identical circuits and to have their respective inputs be 180° out of phase. This can easily be done by a straightforward 180° phase shift circuit 110, as shown in FIG. 8.

Referring now to FIG. 9, a two-channel driver 10′ according to the present invention is shown at the same level of detail as the one-channel driver 10 of FIG. 3. Two-channel driver 10′ of FIG. 9 drives two actuators 12a, 12b via respective driver signals 14a, 14b generated from a control input 32 by respective control circuits 20a, 20b controlling respective power circuits 22a, 22b. The two channel circuit 10′ of FIG. 9 is virtually identical to a dual version of FIG. 3, except the two-channel circuit 10′ includes a 180° phase shift circuit 110 and some of the circuitry need not be duplicated. With the exception of the 180° phase shift circuit 110, the components of FIG. 9 are identical to the components of FIG. 3, discussed above. Those components fall in the range of between 140 and 188, with the one-hundred prefix being added to the corresponding part in FIG. 3. Several components of FIG. 3 need not be duplicated in FIG. 9, such as power supply 24 and signal conditioner 90. The driver circuit 10 preferably accepts a single control input 32 that controls the activation and deactivation of both loads 12a, 12b by driver circuit 10′. The driver circuit 10′ of FIG. 9 more preferably accepts a proportional control input 32 that controls the activation and deactivation of loads 12a, 12b by driver circuit 10′, with one of the driver signals 14a, 14b being approximately proportional to the proportional control input signal 32 and the other driver signal being preferably 180° out of phase with respect thereto; therefore the actuators 12a, 12b are preferably alternately driven.

Referring now to FIG. 10, this figure shows the only additional circuitry needed to make a two-channel version of the driver implementation shown in FIGS. 4A-4I. FIG. 10 shows a 180° phase shift circuit 110 compatible with the driver shown in FIGS. 4A-4I. Thus, to make a two-channel version of the driver implementation shown in FIGS. 4A-4I, one would: (a) duplicate the circuitry shown in FIGS. 4D, 4E, 4G, 4H, and 4I; (b) add an appropriate portion of FIG. 4F (the only circuitry of FIG. 4F that would need to be duplicated would be U7B, R27, U7C, C20, and R30, and their associated connections) (resistor R28 is not duplicated, but is effectively replaced by resistor R58); and (c) connect the circuitry of FIG. 10 between the location indicated on FIG. 4F and the duplicates of amplifier U7C and resistor R27. Of course the connection to resistor R27 would be downstream of resistor R27 and the connection to amplifier U7C would be to the input nodes of U7C (so that R58 and the duplicates of U7C, R27, R30, and C20 function as an inverting summer).

Amplifier U9A and associated resistors R112, R52, and R54, capacitors C108 and C81, and potentiometer R113 function as a 180° phase shift circuit with integration to prevent the possibility that both actuators 12a, 12b are being driven at the same time. The set-point for actuator 12a is a linear function of the voltage applied to the signal input 32, input at connector J4. With an input signal 32 of 0 volts, the actuator driver signal 14a set-point is 0 volts. With an input signal 32 of +12 volts, the actuator driver signal set-point is +200 volts. The signal input 32 is offset, inverted, and scaled by U7A to produce a −3.0 to −12.4 volt swing corresponding to the 0 and +200 volt set-points. The output of amplifier U9A is the opposite. More specifically, the output of amplifier U7A is inverted and offset by U9A to produce the opposite set-points for the second actuator 12b: amplifier U7A outputs of −3.0 and −12.4 volts produce amplifier U9A outputs of −12.4 and −3.0 volts respectively. Except for the 180° inverter U9A, the two control circuits and power circuits are identical and function in accordance with the description set forth above with respect to FIGS. 4A-4I.

Like the circuitry of FIGS. 4A-4I, the two-channel embodiment thereof is optimized for square-wave input signals and its performance suffers during discharging for non-square-wave inputs. In this embodiment, at relatively low input signal frequencies the output signal tracks the input signal very closely. The output signal is generally proportional but not exactly proportional because, at higher frequencies the output signal tracks the input signal quite well as the input signal rises, but because of design considerations discussed below (PWM frequency is sequentially reduced during actuator discharge), as the input signal voltage falls (i.e., as charge is being removed from the load 12) the output signal does not track the input signal quite as well for non-square-wave inputs. In short, the implementation is optimized for square-wave input signals and its performance suffers during discharging for non-square-wave inputs. The performance during discharging for non-square-wave inputs is a result of a design trade-off between a faster discharge time and a better discharge waveform: slowing the PWM frequency during discharge allows for a faster discharge for a square-wave output, but has the effect of distorting non-square-wave outputs. As discussed above, the waveforms of FIGS. 15A-28C show two piezoelectric driver outputs of the type of driver circuit of FIGS. 4D-4I in circuit communication with piezoelectric actuators, responsive to various input signals.

The vast majority of components for the driver 10 of FIGS. 4D-4I, and the two-channel embodiment 10′ thereof, can be readily purchased from common sources. Three notable exceptions to this generalization are the flyback inductors T1 and T2 (the flyback inductor for the second channel is referred to as inductor T2) and the power supply inductor T3. Due to the unique needs of the circuitry of the present invention, inductors T1, T2 and T3 are custom designs. To ensure that they do not saturate (creating excessive power losses and/or damage to other driver components) these parts are sized to operate at a maximum flux density of 0.2 tesla. The design goal temperature rise for these parts was 25° C. To maximize parts commonality, all three inductors are preferably designed around a pair of Philips E34/14/9-3F3 E-core halves and a Philips CPH-E34/14/9-1S-12PD single-section coil former. The core halves are supplied with a 450 μm (0.45 mm) air gap (referenced to a non-gapped core half). A grinding operation opens up the total air-gap for T1 and T2 to 1.26 mm (0.63 mm for each half). Similarly, the total air-gap for T3 is opened up to 1.68 mm.

As to the flyback inductors T1 and T2, the effective magnetic path length of the core set is 69.3 mm. Of this length, 1.26 mm is air, and 68.0 mm is ferrite. The effective area of the ferrite path is 80.7 mm. The 3F3 ferrite has relative permeability of 1800. These and other design parameters (with MKS units) are listed below:

La=1.26 mm (length of air gap)

Lf=68 mm (length of ferrite path)

Af=80.7 mm² (area of ferrite path)

μa=0.4*π*μweber/amp.m (permeability of free space)

K=1800 (relative permeability of 3F3 ferrite)

N=20 (number of turns on each winding)

Aa=(80.7 mm²)*(9.3 mm+1.55 mm)²/(9.3 mm)²=109.8 mm² (area of air path=area of ferrite path with correction for fringing flux)

μf=K*μa (permeability of 3F3 ferrite)

The total reluctance of the magnetic circuit is:

$$\begin{matrix}= ( ferrite path ) + ( air gap ) \\ = Lf / ( μ f * A f ) + La ( μ a * A a ) \\ = 373 , 000 + 9 , 132 , 000 amp * turn / weber \\ = 9.51 amp * turn / µ weber .\end{matrix}$$

The resulting winding inductance is:

L=N²/ [symbol] =42.1 μhenry

With 10 amps of magnetizing current (either winding), the inductor is excited with a magnetomotive force of:

mmf=I*N=200 amp*turns.

The resulting magnetic flux is:

$$\begin{matrix}φ = mmf / \\ = 200 amp * turns / 9.51 amp * turn / µ weber \\ = 21 µ weber ,\end{matrix}$$

The corresponding flux density is:

$$\begin{matrix}B = φ / A f \\ = 21 E \text{-} 06 weber / 80.7 E \text{-} 06 {m}^{2} \\ = 0.26 weber / {meter}^{2} ( i . e . tesla )\end{matrix}$$

Though bi-filar windings would help minimize leakage inductance, the inductor requires high-pot isolation between the primary and secondary windings. The need for electrostatic shielding between the windings also rules out this method of construction. The benefits of using Litz wire appear to be minimal and do not justify the additional assembly costs. However, Litz wire would be suitable for these inductor windings. In the alternative, regular magnet wire can be used instead. The inductor bobbin is first wound with the primary. Appropriate insulation and a foil shield is placed over the primary while avoiding an inadvertent “shorted turn.” The secondary is wound over the shield, followed by a floating copper “belly band.”

Similarly, as to the multi-winding power supply inductor T3, the effective magnetic path length of the core set is 69.3 mm. Of this length, 1.68 mm is air, and 67.6 mm is ferrite. The effective area of the ferrite path is 80.7 mm². The 3F3 ferrite has relative permeability of 1800. These and other design parameters (with MKS units) are listed below:

La=1.68 mm (length of air gap)

Lf=67.6 mm (length of ferrite path)

Af=80.7 mm² (area of ferrite path)

μa=0.4*π*πweber/amp.m (permeability of free space)

K=1800 (relative permeability of 3F3 ferrite)

Np=80 (number of primary turns)

Aa=(80.7 mm²)*(9.3 mm+1.55 mm)²/(9.3 mm)²=109.8 mm² (area of air path=area of ferrite path with correction for fringing flux)

μf=K*μa (permeability of 3F3 ferrite)

The total reluctance of the magnetic circuit is:

$$\begin{matrix}= ( ferrite path ) + ( air gap ) \\ = L f / ( μ f * A f ) + L a / ( μ a * A a ) \\ = 368 , 000 + 12 , 180 , 000 amp * turn / weber \\ = 12.5 amp * turn / µ weber .\end{matrix}$$

The resulting T3 primary winding inductance is:

$$\begin{matrix}L = {N}^{2} / \\ = ( {80}^{2} ) / 12.5 \\ = 512 µ henry\end{matrix}$$

With 2.25 amps of magnetizing current (current limit of U4), the inductor primary is excited with a magnetomotive force of:

mmf=I*N=180 amp*turns.

The resulting magnetic flux is:

$$\begin{matrix}φ = mmf / \\ = 180 amp * turns / 12.5 amp * turn / µ weber \\ = 14.4 µ weber ,\end{matrix}$$

The corresponding flux density is:

$$\begin{matrix}B = φ / A f \\ = 14.4 µ weber / 80.7 {mm}^{2} \\ = 0.18 weber / {meter}^{2} ( i . e . tesla )\end{matrix}$$

As with T1 and T2, there is a need for high-voltage isolation and shielding between the primary and secondary windings of T3. To minimize leakage inductance, the primary is split into two halves. The bobbin is wound first with one of the primary halves. The four secondaries are next wound in sequence. Of these, the first is used as the feedback winding, the next is for the “hot”+15 volt supply, and the last two (which can be bi-filar wound) are for the +/−15 volt supplies referenced to system ground. Finally, the second half of the primary is wound onto the bobbin.

As discussed above, the discharge control system in the implementation of FIGS. 4D-4I, and the two-channel version thereof, controls the peak level of discharge current and switching frequency during a switching cycle of the discharge control system. Because of this, the discharge waveform has unequal steps downward (e.g., as seen in FIGS. 24B and 27B) when the form factor of the input signal 32 is a sinusoid or a tri-angular voltage or another non-square-wave signal. Modifications to the circuitry of FIGS. 4A-4I, and the two-channel embodiment thereof, can allow for an improved “quality” of discharge waveform, relatively fast operation and permit reduced parts count.

One way to reduce parts count as compared to the circuitry of FIGS. 4A-4I, and the two-channel embodiment thereof, is to modify the circuitry to replace the primary control circuit and secondary control circuit with a dual control circuit that controls both the primary side and the secondary side and, therefore, controls both charging and discharging. A driver circuit 210 using such a dual control circuit is shown in block diagram form in FIG. 11. The driver circuit 210 comprises a control circuit 220 controlling a power circuit 222 to generate a driver signal 214 to actuate an actuator 12, e.g., one of the piezoelectric actuators discussed above. The following elements of FIG. 11 (most of which form the power circuit 222) are identical or very similar to that of FIG. 3 and are discussed above: load 12, power supply 24, AC input 26, high-voltage DC signals 28, control input 32, charge storage capacitor 40, transformer 42, primary winding 42a, secondary winding 42b, transformer core 42c, primary switch 44, primary driver 48, secondary driver 50, secondary switch 54, primary current sense 60, primary current signal 62, secondary current sense 64, secondary current signal 66, driver voltage sense 70, voltage signal 72, and signal conditioner 90. As with the driver 10 in FIG. 3, the control circuit 220 of driver 210 in FIG. 11 causes the power circuit 222 to transfer energy from the high-voltage signal 28 and/or from capacitor 40 to the actuator 12.

In the driver 210 of FIG. 11, the primary control circuit 80 and secondary control circuit 82 of FIG. 3 are replaced by a single dual control circuit 230 which generates a PWM control signal 231. The current sense signals 62, 66 are preferably diode-ORed by diodes D200, D202 and placed in circuit communication with dual control circuit 230. The control input 32 is conditioned by signal conditioner 90 and output as conditioned control signal 232. The conditioned control signal 232 is input by a slope detection circuit 234 and a setpoint/feedback circuit 236, which also receives the driver voltage signal 72 from the voltage circuit 70. Slope detect circuit 234 preferably outputs a binary slope signal 238 indicating whether the conditioned control input 232 (and the input 32) is rising or falling. This signal 238 is input by a PWM synchronization circuit 240, which also inputs the PWM control signal 231. PWM synchronization circuit 240 synchronizes the slope signal 238 with the PWM signal 231 to prevent a change in direction of the input signal 32 from being implemented until the next PWM cycle. Accordingly, PWM synchronization circuit 240 generates a synchronized slope signal 242. A PWM routing logic circuit 244 accepts the PWM signal 231 and the synchronized slope signal 242 and generates PWM control signals 246 and 256 used to control switches 44, 54. Depending on the value of the synchronized slope signal 242, the PWM routing logic circuit 244 either (i) routes the PWM signal 231 from the PWM control circuit 230 to the primary switch 44 while turning the secondary switch 54 off (to transfer energy from the primary side to the load 12) or (ii) routes the PWM signal 231 from the PWM control circuit 230 to the secondary switch 54 while turning primary switch 44 off (to transfer energy from the load 12 back to the primary side). PWM control signals 246 and 256 are preferably driven by drivers 48, 50 as driven signals 246′, 256′, which drive respective switches 44, 54.

Thus, in the implementation of FIG. 11, one control circuit (dual control circuit 230) is used to control the charge, regulation and discharge intervals during a switching period of the driver 210. During a charge and regulation interval, dual control circuit 230 controls primary switch Q1 as the central control switch for the system and the secondary switch Q2 is kept OFF during these times. During a discharge interval, the dual control circuit 230 controls secondary switch Q2, keeping the primary switch Q1 in an OFF state. The “switch-over” control decision is made by monitoring the slope of the input signal 32 and using this information to change the routing of the control signal 231 from switch Q1 to switch Q2 or vice-versa. To insure that the “switch-over” time does not occur during a ongoing switching interval of the converter, the slope signal 238 is synchronized to the starting point of the control frequency of the converter system by PWM synchronizer 240, thus preventing any overlap of control which could damage the converter power switches Q1, Q2.

In the circuit of FIG. 11, both the charge and discharge current levels are monitored (via the two current sensors 60, 64) which permits independent adjustment of these currents for fast charge and discharge times.

A two-channel version of the driver 210 shown schematically in FIG. 11 can be made by duplicating most of the circuitry in the same manner that FIG. 3 was modified to be the two-channel circuit of FIG. 9 and by adding a 180° phase shift circuit 110 to phase-shift the conditioned input signal. More specifically, to make a two-channel version of the driver circuit 210 shown in FIG. 11, one must duplicate all of the circuitry in FIG. 11, except for the power supply 24, the signal conditioner 90, and the slope detector 234, and by adding a 180° phase shift circuit 110 to phase-shift the conditioned input signal, which can be readily connected to the duplicate channel based on the teachings of FIGS. 3 and 9.

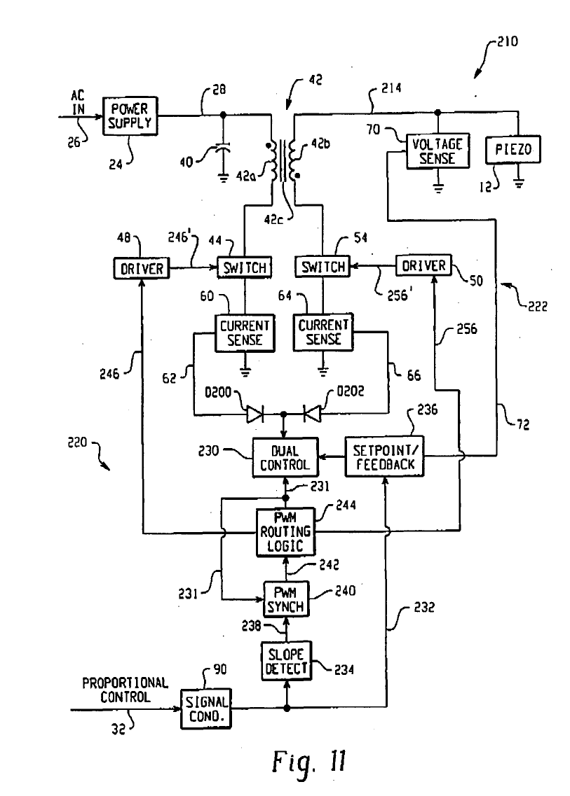

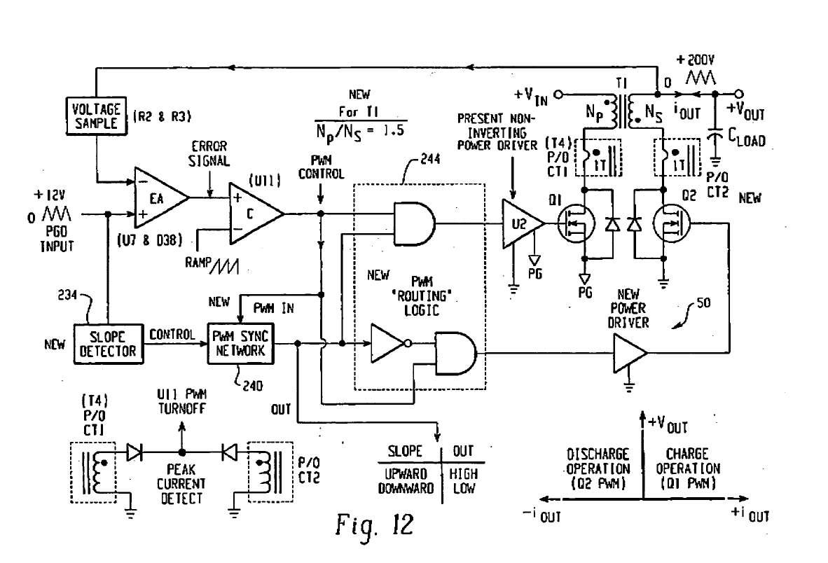

Similarly, the circuitry of FIGS. 4D-4I can be modified to take advantage of the teachings of FIG. 11. FIG. 12 shows a high-level view of changes to the circuitry of FIGS. 4D-4I to implement a version thereof taking advantage of the teachings of FIG. 11. In short, the following changes can be made to the circuitry of FIGS. 4D-4I: (a) the secondary control circuit U12 is removed and both the primary switch Q1 and the secondary switch Q2 are both driven by primary control circuit U11 (changed from part number UC3845A to part number UC3843A, which provides for duty cycles of greater than 50%), which will be renamed “dual control circuit U11” for this implementation because of its dual control role; (b) a slope detector 234, a PWM synchronizing circuit 240, and a PWM routing logic circuit 244 are added to the circuit; (c) the secondary current sensor is changed from being resistor-based to being transformer-based (via the transformer indicated as P/O CT2 in FIG. 12), as with the primary current sensor; and (d) the secondary driver is replaced with the same non-inverting driver used to drive the primary switch Q1.

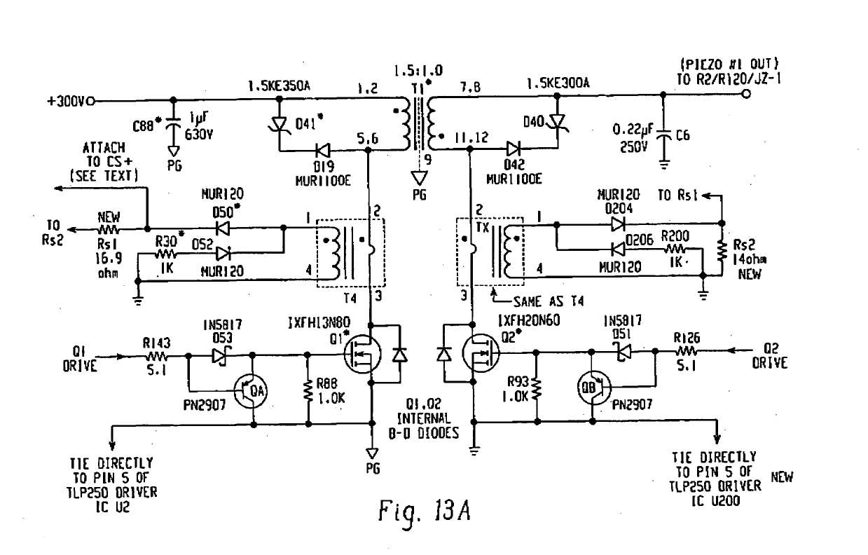

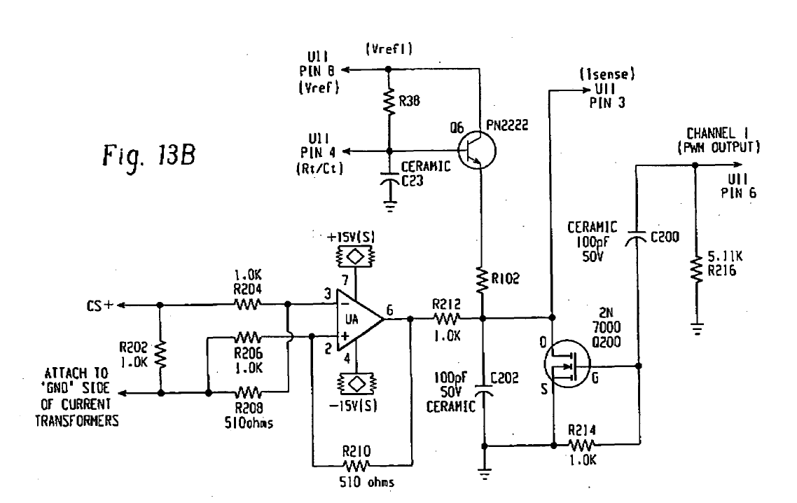

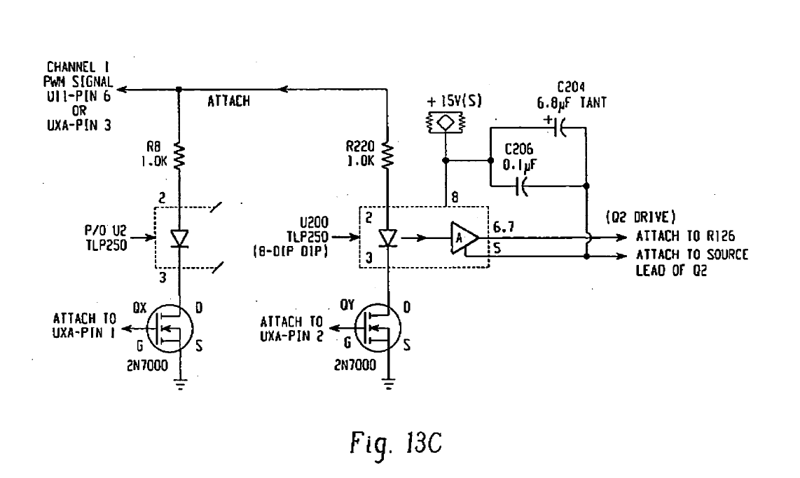

These changes are set forth in more detail in FIGS. 13A-13E. Although the circuits of FIGS. 13A-13C and 13E have not physically made or tested (slope detection circuit 13D was physically made and tested), it is believed that the circuit will function satisfactorily without an inordinate amount of time being spent on adjusting the circuit.

Referring now to FIG. 13A, certain changes to the power circuit of FIGS. 4D and 4E are shown. An asterisk (*) in FIG. 13A indicates that the same type of part is being used, but that a different specific part is being used in FIG. 13A than was used in FIGS. 4D-4I. For example, diode D41 is marked with an asterisk and is indicated as being part number 1.5KE350A. This is a different part than indicated in FIG. 4D, which shows diode D41 as being part number 1.5KE300A. As shown, FIG. 13A makes the following changes to FIGS. 4D and 4E: (i) transistor TX is added to provide a secondary current sense signal, (ii) two diodes D204, D206 and resistor R200 are added and placed in circuit communication with transformer TX as shown, (iii) driver transistors QA and QB are added and connected in circuit communication as shown to more rapidly drain the charge from the gates of transistor switches Q1, Q2 to increase the turn-off speed of these switches, (iv) resistors Rs1 and Rs2 are added and connected in circuit communication as shown and connected together as indicated, (v) a second TLP250 driver chip U200 is added to drive secondary switch Q2 in the same manner that driver U2 drives primary switch Q1, (vi) transformers T4 and TX are moved so as to be connected on the “drain” side of the switches Q1, Q2, which tends to suppress any large transient currents in either sense winding that would otherwise be produced by the drive networks for the switches Q1, Q2, (vii) the input voltage is now 300 volts DC, (viii) with the addition of driver transistors QA and QB, the circuit positions of diodes D51 and D53 are changed as shown in FIG. 13A, (ix) resistors R144, R148, and R21 and capacitor C93 are removed from FIG. 4D, and (x) inductor T1 is redesigned, as discussed below. The outputs of current sense transformers T4, TX are converted to effective voltage levels by their MUR120 diode networks and used to produce a current-sense potential (identified as CS+ in FIGS. 13A and 13B) for the control system. The grounded side of capacitor C88 should be connected directly to the grounded source of primary switch Q1. The leads for components T1, T4, Q1, Q2, and TX should be kept “short and heavy.” Diodes D19, D40, D41, and D42 should be mounted close to transformer T1 with “short” leads. Driver transistors QA and QB should be mounted at the gate-to-source terminals of their respective MOSFET switch Q1, Q2.

Inductor T1 in FIG. 13A is different than inductor T1 in FIG. 4D in order to accommodate the higher input potentials while still retaining the desired primary and secondary inductances for rapid actuator charge and discharge times. The turns ratio of inductor T1 has also been changed from 1:1 in FIG. 4D to 1.5:1 in FIG. 13A, which permits the piezo-capacitance to be charged faster, on the order of 50 micro-seconds nominal, while keeping the peak currents in primary switch Q1 on the same order as they are in the design of FIGS. 4D-4I. Also, because the secondary inductance of inductor T1 is now 50% lower in value, the discharge time of the piezo-capacitance can be reduced to approximately 50 micro-seconds by increasing the peak discharge current level up to approximately 28-amperes. The major design specifications for the new FIG. 13A inductor T1 (and for inductor T2 in a two-channel unit) are as follows: (a) primary side: 30 T formed by 4 strands of #26 AWG wire, (b) secondary side: 20 T formed by 8 strands of #26 AWG wire, (c) Philips E34-3F3 core halves, (d) center leg, (e) air gap length of 3 mm, and (f) L_{1,2-5,6}=58 μH.

Referring now to FIG. 13B, certain changes to the control circuit of FIG. 4H are shown. As shown, FIG. 13B makes the following changes to FIG. 4H: (i) resistors R202, R204, R206, R208, R210, R212, R214, and R216 are added and connected in circuit communication as shown, (ii) capacitors C200 and C202 are added and connected in circuit communication as shown, (iii) transistor Q200 is added and connected in circuit communication as shown, (iv) amplifier UA (Burr-Brown OPA602) is added and connected in circuit communication as shown, (v) the “CS+” node of R202 is connected as shown to diodes D50 and D204 in FIG. 13A, (vi) the other node of resistor R202 is connected as shown to the ground side (pin 4) of the current transformers T4, TX, and (vii) diode D35 and resistor R101 are removed from FIG. 4H.

With the modifications provided by FIG. 13B, the central clock signal for the control circuitry is the current-sense signal CS+ coming from the associated power stage. To maintain a low noise level associated with this signal to prevent control upset, the current-sense signal CS+ is processed through a high-speed differential amplifier network (implemented by amplifier UA, resistors R202, R204, R206, R208, and R210) to insure that ground-generated noise does not interfere with control of the circuit. The resulting signal output by pin 6 of amplifier UA is then summed with a small “artificial” ramp of voltage at the current-sense terminal of the dual control circuit U11 to produce the desired clock “ramp” for the regulation control network within the dual control circuit U11. This artificial ramp is important for control stability purposes for the power stage, particularly when it operates at a duty cycle of 50% or greater when the incoming DC power line is at a minimum level of approximately 200 VDC. Values for the indicated resistances R38, R108 and capacitance C23 might need to be altered based on a stability analysis on an physical circuit implementation for the modified circuit.

The revised control network in FIG. 13B also includes a “blanking” feature to insure that the noise level at the current-sense input (pin 3) to the dual control circuit U11 is eliminated during the time the power stage “switches” are being turned ON and OFF by the control system. This blanking feature is performed by the transistor Q200 (2N7000 MOSFET) and the associated gate resistances R214, R216 and capacitance C200 as illustrated. Each time the dual control circuit U11 starts PWM a PWM cycle, transistor Q200 is turned ON for a short time, forcing the current-sense input (pin 3) to a ground level. Therefore, any noise developed through the incoming current-sense network from the differential amplifier during turn-on or turn-off of the switches Q1, Q2 is shunted through transistor Q200 while it is ON. The value of the gate drive capacitance C200 for this transistor is chosen to keep the transistor in a conducting state for only a short portion of time at the start of a PWM switching period.

Referring now to FIG. 13C, certain changes to the driver circuitry of FIG. 4D are shown. As shown, FIG. 13C makes the following changes to FIG. 4D: (i) transistors QX and QY are added and connected in circuit communication as shown, (ii) the second driver chip U200 is added and connected in circuit communication as shown, (iii) resistor R220 is added and connected in circuit communication as shown, (iv) capacitors C204 and C206 are added and connected in circuit communication as shown, (v) driver chip U200 is connected to resistor R126 and the source of switch Q2 (FIG. 13A), (vi) the PWM signal from pin 6 of dual control circuit U11 is connected to both resistor R8 and resistor R220, and (vii) the cathode (pin 3) of driver U2 is changed to be connected to the system ground via new transistor QX and the cathode (pin 3) of driver U200 is connected to the system ground via new transistor QY. As indicated, the gates of transistors QX and QY are connected to pins 1 and 2, respectively, of latch UXA, which is shown in FIG. 13D.

Transistors QX and QY permit selection of which switch Q1, Q2 is being activated by the PWM signal from dual control circuit U11. These transistors effectively “route” the PWM signal (pin 6 of U11) to one switch Q1, Q2 or the other based on the state of latch UXA. Thus, transistors QX and QY form part of the routing logic 244 in FIGS. 11 and 12.

Referring now to FIG. 13D, the slope detect circuit 234, PWM synchronizing circuit 240, and remaining portion of the routing logic 244 are shown. All of the components shown in FIG. 13D are added and connected in circuit communication as shown in that figure. Operational amplifiers A1A, A1B, and A1C, and components RX, CX, R222, R224, R226, R228, D208, and D210 form a slope detection circuit 234. The slope of the input signal 32 (or the conditioned input signal 232) is determined by comparing the incoming signal against a “shadow” of itself to produce a logic level that represents whether the slope is increasing or decreasing in magnitude. The “shadow” signal is developed by processing the original signal through a unity-gain operational amplifier network that introduces a small phase lag. More specifically to the circuitry shown in FIG. 13D, amplifier A1B introduces the small phase lag, with resistor RX and capacitor CX setting the desired phase lag amount. The phase lag value determines the sensitivity of the slope detector 234 is set to accommodate virtually any type of incoming signal format that could be present (e.g., pulse, square-wave, sinusoid, triangle, etc.) without additional adjustment. Amplifier A1C is used as a comparator to compare the original input signal (obtained from buffer amplifier A1A) against its “shadow” generated by amplifier A1B. In response, comparator A1C produces a logical “one” voltage of approximately +14 VDC when the incoming signal is “increasing” in slope, and a logical “zero” value of −14 VDC when the incoming signal is “decreasing” in slope. Diode D210 causes the resulting slope signal 238 to be a logical “one” voltage of approximately +14 VDC when the incoming signal is “increasing” in slope, and a logical “zero” value of 0 VDC when the incoming signal is “decreasing” in slope.

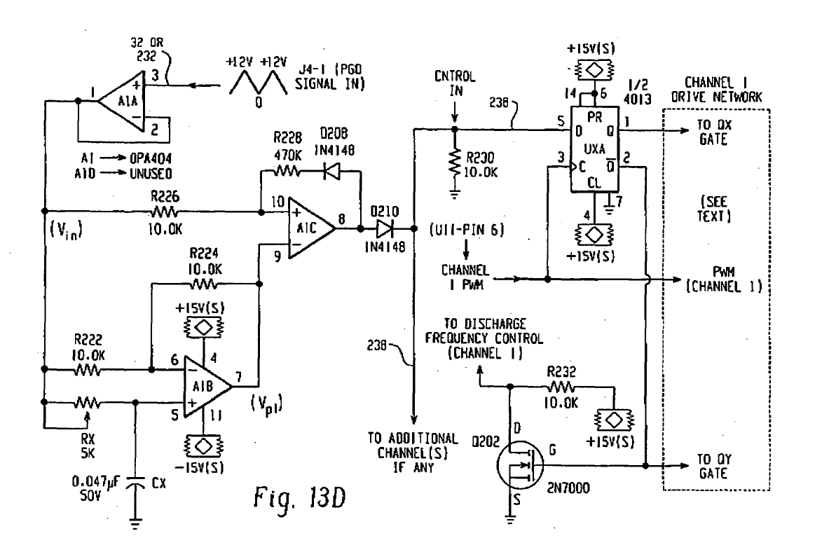

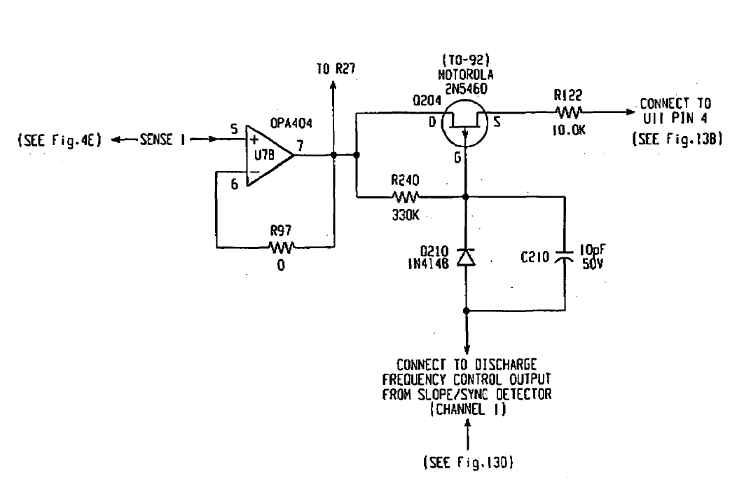

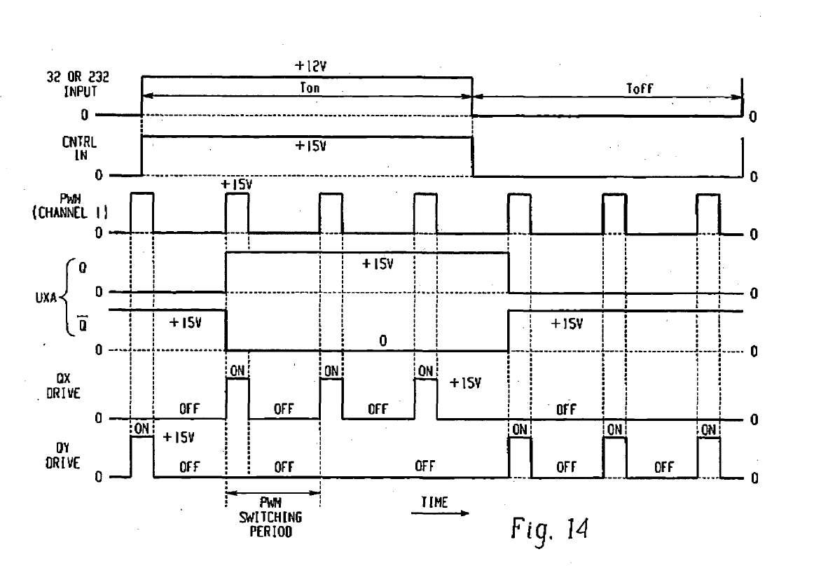

D-type flip-flop UXA performs the PWM synchronization function and, thus, forms PWM synchronization circuit 240. The PWM signal from pin 6 of dual control circuit U11 provides the clock input to flip-flop UXA and the slope signal 238 is the data (D) input to flip-flop UXA. Thus, the leading edge of the input signal from the dual control chip U11 provides synchronization. The signal relationships associated with the inputs and outputs of flip-flop UXA are shown in FIG. 14. Notice that when the INPUT signal 32 (or 232) is high, output Q of UXA is active driving transistor QX, which routes the PWM signal to primary side switch Q1 via driver U2 (FIG. 13C) (the output of driver U2 controlled by transistor QX is shown as QX DRIVE in FIG. 14) and when the INPUT signal 32 (or 232) is low, the inverted Q output (Q-bar) of UXA is active driving transistor QY, which routes the PWM signal to primary side switch Q2 via driver U200 (FIG. 13C) (the output of driver U200 controlled by transistor QY is shown as QY DRIVE in FIG. 14). Notice also that even though the INPUT signal in FIG. 14 transitions between PWM pulses, there is no effect on the outputs of UXA until the next PWM control pulse. Thus, in the modification of FIGS. 13A-13E, the flip-flop UXA performs the functions of both the PWM synchronization circuit 240 and the PWM routing logic 244 in FIG. 11.

Recall that it is an object of the present invention to provide a circuit for use with square wave inputs that includes the capability of allowing the frequency of its discharge control circuit to be varied in accord with the output voltage 14 to accelerate the discharge process. The circuitry shown in FIGS. 4D-4I (and the two-channel version thereof) included the feature of varying the discharge frequency as the piezoelectric element 12 is discharged, i.e., reducing the operating frequency of secondary control chip U12 based on the dropping voltage provided by the voltage divider voltage feedback circuit formed by resistors R2 and R3. As discussed above, this feature allows more rapid discharge of the charge stored on the piezoelectric element 12, but results in a sacrifice of output signal quality at higher operating frequencies for non-pulsed input control signals. The modifications to that circuit shown in FIGS. 13A-13D and discussed above do not include such variable discharge frequency control. If discharge frequency control is desirable to be added, it can be added to the modified circuit by adding transistor Q202 and resistor R232 as shown in FIG. 13D and by adding the additional circuitry (resistor P240, capacitor C210, diode D210, and transistor Q204) shown in FIG. 13E. These additional modifications allow the slope detector circuitry to alter the PWM clock frequency so as to be controlled by the output voltage of the driver signal 14 driving the piezoelectric element. The switch for this control mechanism is the Q202 2N7000 MOSFET in FIG. 13D. The control signal is interfaced to pin 4 of dual control chip U11 by the circuitry added in FIG. 13E.

The one-channel driver represented by the various modifications of FIGS. 13A-13E to the circuit of FIGS. 4D-4I can be converted to be a two-channel driver in the same manner that the one-channel circuit of FIGS. 4D-4I was converted to be a two-channel circuit as discussed above by duplicating a majority of the circuitry for the second channel and adding the 180° phase shift circuit 110 of FIG. 10. As before, some of the circuit need not be duplicated to make a two-channel driver, e.g., the slope detector circuit comprised of amplifiers A1A, A1B, and A1C and associated discrete components need not be duplicated.

While the present invention has been illustrated by the description of embodiments thereof, and while the embodiments have been described in some detail, it is not the intention of the applicant to restrict or in any way limit the scope of the appended claims to such detail. Additional advantages and modifications will readily appear to those skilled in the art. Therefore, the invention in its broader aspects is not limited to the specific details, representative apparatus and methods, and illustrative examples shown and described. Accordingly, departures may be made from such details without departing from slope detector circuit the spirit or scope of the applicant's general inventive concept.

What is claimed is:

1. A driver circuit for driving a high-capacitance load, comprising:
(a) a voltage source having a charge storage device at a voltage output thereof;
(b) a power circuit in circuit communication with said voltage source at said voltage output and for being placed in circuit communication with the high-capacitance load; and
(c) a control circuit accepting a control input, said control circuit in circuit communication with said power circuit and controlling said power circuit to cause the charging and discharging of said high-capacitance load responsive to the control input, said control circuit characterized by operating as a bidirectional converter in which electrical energy is transferred from said charge storage device to said high-capacitance load as said high-capacitance load is charged and electrical energy is transferred back from said high-capacitance load to said charge storage device as said high-capacitance load is discharged.

2. The driver circuit according to claim 1 wherein said control circuit functions as a bidirectional switch mode converter having at least one operating frequency, and the at least one operating frequency of said control circuit is reduced during high-capacitance load discharge, thereby causing said high-capacitance load to be discharged faster than if the at least one operating frequency were not reduced.

3. The driver circuit according to claim 2 wherein the at least one operating frequency of said control circuit is a function of the voltage across the high-capacitance load.

4. The driver circuit according to claim 3 wherein the at least one operating frequency of said control circuit is proportional to the voltage across the high-capacitance load.

5. The driver circuit according to claim 1 wherein said control circuit functions as a switch mode converter operating in at least two sequential energy storage modes while said high-capacitance load is being charged, namely a current-controlled continuous-conduction (CCCC) energy storage mode and a current-controlled discontinuous-conduction (CCDC) energy storage mode.

6. The driver circuit according to claim 1 wherein said control circuit functions as a switch mode converter operating in at least three sequential energy storage modes while said high-capacitance load is being charged, namely a current-controlled continuous-conduction (CCCC) energy storage mode, a current-controlled discontinuous-conduction (CCDC) energy storage mode, and a voltage-controlled discontinuous-conduction (VCDC) energy storage mode.

7. The driver circuit according to claim 1 wherein said control circuit functions as a switch mode converter having at least one operating frequency, and the at least one operating frequency of said control circuit is reduced during high-capacitance load discharge, and further wherein said control circuit operates in at least two sequential energy storage modes while said high-capacitance load is being charged, namely a current-controlled continuous-conduction (CCCC) energy storage mode and a current-controlled discontinuous-conduction (CCDC) energy storage mode.

8. The driver circuit according to claim 1 wherein said control circuit functions as a switch mode converter having at least one operating frequency, and the at least one operating frequency of said control circuit is reduced during high-capacitance load discharge, and further wherein said control circuit operates in at least three sequential energy storage modes while said high-capacitance load is being charged, namely a current-controlled continuous-conduction (CCCC) energy storage mode, a current-controlled discontinuous-conduction (CCDC) energy storage mode, and a voltage-controlled discontinuous-conduction (VCDC) energy storage mode.

9. The driver circuit according to claim 1 wherein said control circuit comprises first and second control units in circuit communication with said power circuit;
(a) said first control unit characterized by primarily controlling the charging of said high-capacitance load by said power circuit; and
(b) said second control unit characterized by primarily controlling the discharging of said high-capacitance load by said power circuit.

10. The driver circuit according to claim 1 wherein said control circuit comprises a single control unit in circuit communication with said power circuit, said single control unit being characterized by controlling both the charging and the discharging of said high-capacitance load by said power circuit.

11. The driver circuit according to claim 10 wherein said control circuit comprises a slope detector in circuit communication with the control input and in circuit communication with said single control unit to cause said single control unit to control said power circuit to either charge the high-capacitance load or discharge the high-capacitance load, depending on the slope of the control input.

12. The driver circuit according to claim 1 wherein said control circuit controls said power circuit to charge the high-capacitance load to a voltage related to a parameter of the control input.

13. The driver circuit according to claim 1 wherein said control circuit controls said power circuit to charge the high-capacitance load to a voltage proportional to the voltage of the control input.

14. The driver circuit according to claim 1 wherein said control circuit controls said power circuit to charge the high-capacitance load to greater than 150 VDC.

15. The driver circuit according to claim 1 wherein said control circuit controls said power circuit to charge the high-capacitance load to about 160 VDC.

16. The driver circuit according to claim 1 wherein said control circuit controls said power circuit to charge the high-capacitance load to about 150 to 200 VDC.

17. The driver circuit according to claim 1 wherein said driver circuit is capable of charging the high-capacitance load to about 100 VDC in about 100 microseconds or less.

18. The driver circuit according to claim 1 wherein said driver circuit is capable of charging the high-capacitance load to about 150 VDC in about 150 microseconds or less.

19. The driver circuit according to claim 1 wherein said driver circuit is capable of charging the high-capacitance load to about 200 VDC in about 300 microseconds or less.

20. The driver circuit according to claim 1 wherein said driver circuit is capable of charging a high-capacitance load having a capacitance of about 2.5 μF to about 100 VDC in about 100 microseconds or less.

21. The driver circuit according to claim 1 wherein said driver circuit is capable of charging a high-capacitance load having a capacitance of about 2.5 μF to about 150 VDC in about 150 microseconds or less.

22. The driver circuit according to claim 1 wherein said driver circuit is capable of charging a high-capacitance load having a capacitance of about 2.5 μF to about 200 VDC in about 300 microseconds or less.

23. A driver circuit for driving a high-capacitance load, comprising:
(a) an inductor having a primary side, a secondary side, and a gapped core, said secondary side for being placed in circuit communication with said high-capacitance load;
(b) a power source in circuit communication with said primary side;
(c) a charge storage device in circuit communication with said primary side;
(d) a primary side switch in circuit communication with said primary side and characterized by selectively causing current from at least one of said power source and said charge storage device to conduct through said primary side;
(e) a secondary side switch in circuit communication with said secondary side and characterized by selectively causing current from the high-capacitance load to conduct through said secondary side; and
(f) a control circuit in circuit communication with said primary side switch and said secondary side switch so as to control the charging and discharging of said high-capacitance load by said switches responsive to a control input, said control circuit characterized by operating in a switching mode as a bidirectional flyback converter in which energy is transferred from said charge storage device to said high-capacitance load as said high-capacitance load is charged and energy is transferred back from said high-capacitance load to said charge storage device as said high-capacitance load is discharged.

24. The driver circuit according to claim 23 wherein said control circuit functions as a bidirectional switch mode flyback converter having at least one operating frequency, and the at least one operating frequency of said control circuit is reduced during high-capacitance load discharge, thereby causing said high-capacitance load to be discharged faster than if the at least one operating frequency were not reduced.

25. The driver circuit according to claim 24 wherein the at least one operating frequency of said control circuit a function of the voltage across the high-capacitance load.

26. The driver circuit according to claim 24 wherein the at least one operating frequency of said control circuit is proportional to the voltage across the high-capacitance load.

27. The driver circuit according to claim 23 wherein said control circuit functions as a bidirectional switch mode flyback converter operating in at least two sequential energy storage modes while said high-capacitance load is being charged, namely a current-controlled continuous-conduction (CCCC) energy storage mode and a current-controlled discontinuous-conduction (CCDC) energy storage mode.

28. The driver circuit according to claim 23 wherein said control circuit functions as a bidirectional switch mode flyback converter operating in at least three sequential energy storage modes while said high-capacitance load is being charged, namely a current-controlled continuous-conduction (CCCC) energy storage mode, a current-controlled discontinuous-conduction (CCDC) energy storage mode, and a voltage-controlled discontinuous-conduction (VCDC) energy storage mode.

29. The driver circuit according to claim 23 wherein said control circuit functions as a bidirectional switch mode flyback converter having at least one operating frequency, and the at least one operating frequency of said control circuit is reduced during high-capacitance load discharge, and further wherein said control circuit operates in at least two sequential energy storage modes while said high-capacitance load is being charged, namely a current-controlled continuous-conduction (CCCC) energy storage mode and a current-controlled discontinuous-conduction (CCDC) energy storage mode.

30. The driver circuit according to claim 23 wherein said control circuit functions as a bidirectional switch mode flyback converter having at least one operating frequency, and the at least one operating frequency of said control circuit is reduced during high-capacitance load discharge, and further wherein said control circuit operates in at least three sequential energy storage modes while said high-capacitance load is being charged, namely a current-controlled continuous-conduction (CCCC) energy storage mode, a current-controlled discontinuous-conduction (CCDC) energy storage mode, and a voltage-controlled discontinuous-conduction (VCDC) energy storage mode.

31. The driver circuit according to claim 23 wherein said control circuit comprises a first control unit in circuit communication with and controlling said primary side switch and a second control unit in circuit communication with and controlling said secondary side switch;
(a) said first control unit characterized by primarily controlling the charging of said high-capacitance load by said primary side switch; and
(b) said second control unit characterized by primarily controlling the discharging of said high-capacitance load by said secondary side switch.

32. The driver circuit according to claim 23 wherein said control circuit comprises a single control unit in circuit communication with and controlling said primary side switch and said secondary side switch, said single control unit being characterized by controlling both the charging of said high-capacitance load by said primary side switch and the discharging of said high-capacitance load by said secondary side switch.

33. The driver circuit according to claim 32 wherein said control circuit comprises a slope detector in circuit communication with the control input and in circuit communication with said single control unit to cause said single control unit to control said first and second switches to either charge the high-capacitance load or discharge the high-capacitance load, depending on the slope of the control input.

34. The driver circuit according to claim 23 wherein said control circuit controls said first and second switches to charge the high-capacitance load to a voltage related to a parameter of the control input.

35. The driver circuit according to claim 23 wherein said control circuit controls said first and second switches to charge the high-capacitance load to a voltage proportional to the voltage of the control input.

36. The driver circuit according to claim 23 wherein said control circuit controls said first and second switches to charge the high-capacitance load voltages to greater than 150 VDC.

37. The driver circuit according to claim 23 wherein said control circuit controls said first and second switches to charge the high-capacitance load to about 160 VDC.

38. The driver circuit according to claim 23 wherein said control circuit controls said first and second switches to charge the high-capacitance load to about 200 VDC.

39. The driver circuit according to claim 23 wherein said driver circuit is capable of charging the high-capacitance load to about 100 VDC in about 100 microseconds or less.

40. The driver circuit according to claim 23 wherein said driver circuit is capable of charging the high-capacitance load to about 150 VDC in about 150 microseconds or less.

41. The driver circuit according to claim 23 wherein said driver circuit is capable of charging the high-capacitance load to about 200 VDC in about 300 microseconds or less.

42. The driver circuit according to claim 23 wherein said driver circuit is capable of charging a high-capacitance load having a capacitance of about 2.5 μF to about 100 VDC in about 100 microseconds or less.

43. The driver circuit according to claim 23 wherein said driver circuit is capable of charging a high-capacitance load having a capacitance of about 2.5 μF to about 150 VDC in about 150 microseconds or less.

44. The driver circuit according to claim 23 wherein said driver circuit is capable of charging a high-capacitance load having a capacitance of about 2.5 μF to about 200 VDC in about 300 microseconds or less.

45. A driver circuit for driving a high-capacitance load, comprising:
(a) An inductor having a primary side, a secondary side, and a gapped core, said secondary side for being placed in circuit communication with said high-capacitance load;
(b) a power source in circuit communication with said primary side;
(c) a charge storage device in circuit communication with said primary side;
(d) a primary side switch in circuit communication with said primary side and characterized by selectively causing current from at least one of said power source and said charge storage device to conduct through said primary side;
(e) a secondary side switch in circuit communication with said secondary side and characterized by selectively causing current from the high-capacitance load to conduct through said secondary side; and
(f) a control circuit in circuit communication with said primary side switch and said secondary side switch so as to control the charging and discharging of said high-capacitance load by said switches responsive to a control input, said control circuit characterized by operating in a switching mode as a bidirectional flyback converter in which energy is transferred from said charge storage device to said high-capacitance load as said high-capacitance load is charged and energy is transferred back from said high-capacitance load to said charge storage device as said high-capacitance load is discharged; and
wherein said control circuit functions as a bidirectional switch mode flyback converter having at least one operating frequency, and the at least one operating frequency of said control circuit is reduced during high-capacitance load discharge, thereby causing said high-capacitance load to be discharged faster than if the at least one operating frequency were not reduced;
wherein the at least one operating frequency of said control circuit is proportional to the voltage across the high-capacitance load;
wherein said control circuit functions as a bidirectional switch mode flyback converter operating in at least three sequential energy storage modes while said high-capacitance load is being charged, namely a current-controlled continuous-conduction (CCCC) energy storage mode, a current-controlled discontinuous-conduction (CCDC) energy storage mode, and a voltage-controlled discontinuous-conduction (VCDC) energy storage mode; and
wherein said control circuit controls said first and second switches to charge the high-capacitance load to a voltage proportional to the voltage of the control input.

46. The driver circuit according to claim 45 wherein said control circuit comprises a first control unit in circuit communication with and controlling said primary side switch and a second control unit in circuit communication with and controlling said secondary side switch;
(a) said first control unit characterized by primarily controlling the charging of said high-capacitance load by said primary side switch; and
(b) said second control unit characterized by primarily controlling the discharging of said high-capacitance load by said secondary side switch.

47. The driver circuit according to claim 45 wherein said control circuit comprises a single control unit in circuit communication with and controlling said primary side switch and said secondary side switch, said single control unit being characterized by controlling both the charging of said high-capacitance load by said primary side switch and the discharging of said high-capacitance load by said secondary side switch.

48. The driver circuit according to claim 47 wherein said control circuit comprises a slope detector in circuit communication with the control input and in circuit communication with said single control unit to cause said single control unit to control said first and second switches to either charge the high-capacitance load or discharge the high-capacitance load, depending on the slope of the control input.
